(19) United States
(12) Patent Application Publication
(10) Pub. No.: US 2023/0295494 A1
(43) Pub. Date: Sep. 21, 2023

(54) PHOTODETECTION ELEMENT AND IMAGE SENSOR

(71) Applicant: FUJIFILM Corporation, Tokyo (JP)

(72) Inventors: Masashi ONO, Shizuoka (JP); Hirotaka Satou, Shizuoka (JP)

(73) Assignee: FUJIFILM Corporation, Tokyo (JP)

(21) Appl. No.: 18/171,385

(22) Filed: Feb. 20, 2023

Related U.S. Application Data
(63) Continuation of application No. PCT/JP2021/032576, filed on Sep. 6, 2021.

(30) Foreign Application Priority Data
Sep. 10, 2020 (JP) 2020-151847

(51) Int. Cl. C09K 11/74; H10K 85/10; H10K 85/60; H10K 85/40; H10K 85/20

(52) U.S. Cl. CPC C09K 11/7407; H10K 85/113; H10K 85/215; H10K 85/40; H10K 85/654; H10K 85/657; H10K 85/6576; H10K 39/32

(57) ABSTRACT

There are provided a photodetection element including a first electrode layer 11, a second electrode layer 12, a photoelectric conversion layer 13 provided between the first electrode layer 11 and the second electrode layer 12, an electron transport layer 21 provided between the first electrode layer 11 and the photoelectric conversion layer 13, and a hole transport layer 22 provided between the photoelectric conversion layer 13 and the second electrode layer 12, in which the photoelectric conversion layer 13 contains quantum dots of a compound semiconductor containing an Ag element and a Bi element, and the hole transport layer 22 contains an organic semiconductor A including a predetermined structure, and are provided an image sensor.

### CROSS-REFERENCE TO RELATED APPLICATIONS

This application is a Continuation of PCT International Application No. PCT/JP2021/032576 filed on Sep. 6, 2021, which claims priority under 35 U.S.C §119(a) to Japanese Patent Application No. 2020-151847 filed on Sep. 10, 2020. Each of the above application(s) is hereby expressly incorporated by reference, in its entirety, into the present application.

### BACKGROUND OF THE INVENTION

### 1. Field of the Invention

The present invention relates to a photodetection element having a photoelectric conversion layer that contains semiconductor quantum dots and an image sensor.

### 2. Description of the Related Art

In recent years, attention has been focused on photodetection elements capable of detecting light in the infrared region in the fields such as smartphones, surveillance cameras, and in-vehicle cameras.

In the related art, a silicon photodiode in which a silicon wafer is used as a material of a photoelectric conversion layer has been used in a photodetection element that is used for an image sensor or the like. However, a silicon photodiode has low sensitivity in the infrared region having a wavelength of 900 nm or more.

In addition, an InGaAs-based semiconductor material known as a near-infrared light-receiving element has a problem in that it requires extremely high-cost processes such as epitaxial growth or a step of sticking a substrate in order to realize a high quantum efficiency, and thus it has not been widespread.

By the way, in recent years, research on quantum dots has been advanced. A solar battery cell having a photoelectric conversion film containing quantum dots of AgBiS₂ is disclosed in M. D. Bernechea et. al., “Solution-processed solar cells based on environmentally friendly AgBiS₂ nanocrystals” Nature Photos, 10, 521-525 (2016), and Hu et, al., “Enhanced optoelectronic performance in AgBiS₂ nanocrystals obtained via an improved amine-based synthesis route”, Journal of Materials Chemistry C6, 731 (2018).

### SUMMARY OF THE INVENTION

In recent years, with the demand for performance improvement of an image sensor and the like, further improvement of various characteristics that are required in a photodetection element used in the image sensor and the like is also required. For example, one of the characteristics required in the photodetection element is to have a high external quantum efficiency with respect to light having a target wavelength to be detected by the photodetection element. In a case of increasing the external quantum efficiency of the photodetection element, it is possible to increase the accuracy of detecting light in the photodetection element.

In addition, in the photodetection element, it is preferable that the dark current is low. In a case where the dark current of the photodetection element is reduced, a higher signal-to-noise ratio (SN ratio) can be obtained in the image sensor. The dark current is a current that flows in a case of not being irradiated with light.

As a result of diligently studying the solar battery cells disclosed in M. D. Bernechea et. al., “Solution-processed solar cells based on environmentally friendly AgBiS2 nanocrystals” Nature Photos, 10, 521-525 (2016), and Hu et, al., “Enhanced optoelectronic performance in AgBiS2 nanocrystals obtained via an improved amine-based synthesis route”, Journal of Materials Chemistry C6, 731 (2018), the inventors of the present invention found that these solar battery cells have a low external quantum efficiency with respect to light having a wavelength in the infrared region (particularly, light having a wavelength of 900 nm or more). In addition, dark current was found to be relatively high.

Accordingly, an object of the present invention is to provide a photodetection element in which the external quantum efficiency is high with respect to light having a wavelength in the infrared region and the dark current is reduced, and an image sensor.

According to the study of the inventors of the present invention, it was found that the above problems can be solved by adopting the following configurations, whereby the present invention was completed. The present invention provides the following aspects.
<1> A photodetection element comprising:
   a first electrode layer;
   a second electrode layer;
   a photoelectric conversion layer provided between the first electrode layer and the second electrode layer;
   an electron transport layer provided between the first electrode layer and the photoelectric conversion layer; and
   a hole transport layer provided between the photoelectric conversion layer and the second electrode layer,
   in which the photoelectric conversion layer contains quantum dots of a compound semiconductor containing an Ag element and a Bi element, and
   the hole transport layer contains an organic semiconductor A including a structure represented by any one of Formulae 3-1 to 3-5, 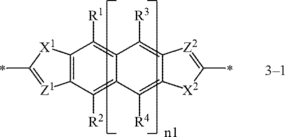 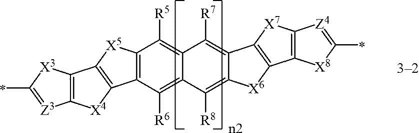 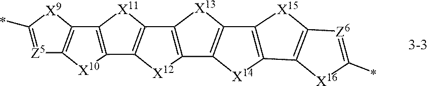 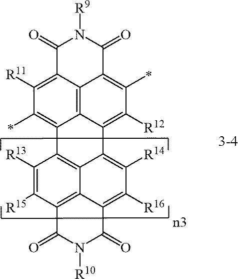 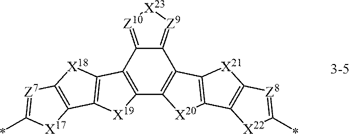
   in Formula 3-1, X¹ and X² each independently represent S, O, Se, NR^{X1}, or CR^{X2}R^{X3}, where R^{X1} to R^{X3} each independently represent a hydrogen atom or a substituent,
   R¹ to R⁴ each independently represent a hydrogen atom or a substituent,
   n1 represents an integer of 0 to 2, and
   * represents a bonding site,
   provided that at least one of R¹ or R² represents a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, a group represented by Formula (R-100), or a group including an intramolecular salt structure,
   -L¹⁰⁰-R¹⁰⁰ ... (R- 100)
   in (R-100), L¹⁰⁰ represents a single bond or a divalent group, and R¹⁰⁰ represents an acid group, a basic group, a group having an anion, or a group having a cation;
   in Formula 3-2, X³ to X⁸ each independently represent S, O, Se, NR^{X4}, or CR^{X5}R^{X6}, where R^{X4} to R^{X6} each independently represent a hydrogen atom or a substituent,
   Z³ and Z⁴ each independently represent N or CR^{Z2}, where R^{Z2} represents a hydrogen atom or a substituent,
   R⁵ to R⁸ each independently represent a hydrogen atom or a substituent,
   n2 represents an integer of 0 to 2, and
   * represents a bonding site,
   in Formula 3-3, X⁹ to X¹⁶ each independently represent S, O, Se, NR^{X7}, or CR^{X8}R^{X9}, where R^{X7} to R^{X9} each independently represent a hydrogen atom or a substituent,
   Z⁵ and Z⁶ each independently represent N or CR^{Z3}, where R^{Z3} represents a hydrogen atom or a substituent, and
   * represents a bonding site,
   in Formula 3-4, R⁹ to R¹⁶ each independently represent a hydrogen atom or a substituent, n3 represents an integer of 0 to 2, and
   * represents a bonding site,
   in Formula 3-5, X¹⁷ to X²³ each independently represent S, O, Se, NR^{X1}°, or CR^{X11}R^{X12}, where R^{X10} to R^{X12} each independently represent a hydrogen atom or a substituent,
   Z⁷ to Z¹⁰ each independently represent N or CR^{Z4}, where R^{Z4} represents a hydrogen atom or a substituent, and
   * represents a bonding site.
<2> The photodetection element according to <1>, in which the organic semiconductor A is a compound including a structure represented by Formula 3-1 or a compound including a structure represented by Formula 3-4.
<3> The photodetection element according to <1> or <2>, in which the organic semiconductor A further includes a structure represented by Formula 4,

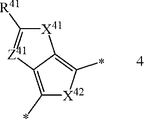

in Formula 4, X⁴¹ and X⁴² each independently represent S, O, Se, NR^{X41}, or CR^{X42}R^{X43}, where R^{X41} to R^{X43} each independently represent a hydrogen atom or a substituent,
Z⁴¹ represents N or CR^{Z41}, where R^{Z41} represents a hydrogen atom or a substituent, R⁴¹ represents a hydrogen atom or a substituent, and
* represents a bonding site.
<4> The photodetection element according to any one of <1> to <3>, in which the organic semiconductor A has a group represented by Formula (R-100) or a group including an intramolecular salt structure.
<5> The photodetection element according to <1>, in which the organic semiconductor A is a compound including a structure represented by Formula 5,

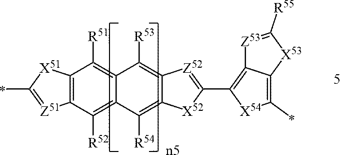

in Formula 5, X⁵¹ to X⁵⁴ each independently represent S, O, Se, NR^{X51}, or CR^{X52}R^{X53}, where R^{X51} to R^{X53} each independently represent a hydrogen atom or a substituent,
Z⁵¹ to Z⁵³ each independently represent N or CR^{Z51}, where R^{Z51} represents a hydrogen atom or a substituent,
R⁵¹ to R⁵⁵ each independently represent a hydrogen atom or a substituent,
n5 represents an integer of 0 to 2, and
* represents a bonding site,
provided that at least one of R⁵¹ or R⁵² represents a halogen atom, a hydroxy group, a cyano group, an amino group, an acylamino group, an acyloxy group, a carboxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, the group represented by Formula (R-100), or a group including an intramolecular salt structure.
<6> The photodetection element according to any one of <1> to <5>, in which the hole transport layer contains two or more kinds of the organic semiconductors A.
<7> The photodetection element according to any one of <1> to <5>, in which the hole transport layer contains the organic semiconductor A and an organic semiconductor other than the organic semiconductor A.
<8> The photodetection element according to <7>, in which the organic semiconductor other than the organic semiconductor A is a fullerene-based organic semiconductor.
<9> The photodetection element according to any one of <1> to <8>, in which the compound semiconductor of the quantum dots further contains at least one element selected from an element S or an element Te.
<10> The photodetection element according to any one of <1> to <9>, in which the photoelectric conversion layer contains a ligand that is coordinated to the quantum dots.
<11> The photodetection element according to <10>, in which the ligand contains at least one selected from a ligand containing a halogen atom or a polydentate ligand containing two or more coordination moieties.
<12> An image sensor comprising the photodetection element according to any one of <1> to <11>.

According to the present invention, it is possible to provide a photodetection element in which the external quantum efficiency is high and the dark current is reduced, and an image sensor.

### BRIEF DESCRIPTION OF THE DRAWINGS

FIG. 1 is a view illustrating an embodiment of a photodetection element.

### DESCRIPTION OF THE PREFERRED EMBODIMENTS

Hereinafter, the contents of the present invention will be described in detail.

In the present specification, “to” is used to mean that numerical values described before and after “to” are included as a lower limit value and an upper limit value, respectively.

In describing a group (an atomic group) in the present specification, in a case where a description of substitution and non-substitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

### Photodetection Element

The photodetection element according to the embodiment of the present invention is characterized by the following facts;
the photodetection element includes a first electrode layer,
a second electrode layer,
a photoelectric conversion layer provided between the first electrode layer and the second electrode layer,
an electron transport layer provided between the first electrode layer and the photoelectric conversion layer, and
a hole transport layer provided between the photoelectric conversion layer and the second electrode layer,
in which the photoelectric conversion layer contains quantum dots of a compound semiconductor containing an Ag element and a Bi element, and
the hole transport layer contains an organic semiconductor A including a structure represented by any one of Formulae 3-1 to 3-5.

According to the present invention, it is possible for the photodetection element to have a high external quantum efficiency and have a low dark current.

Here, according to the study by the inventors of the present invention, in a case where, among the organic semiconductors including the structure represented by Formula 3-1, a compound including a structure in which both R¹ and R² are an alkoxy group, such as poly({4,8-bis[(2-ethylhexyl)oxy]benzo[1,2-b:4,5-b′]dithiophen-2,6-diyl}{f3-fluoro-2-[(2-ethylhexyl)carbonyl]thieno[3,4-b]thiophendiyl}) (a compound having the following structure), is used for the hole transport layer, sufficient external quantum efficiency cannot be obtained, and furthermore, the dark current tends to be high. The reason for this is presumed as follows; in a case where both R¹ and R² of the structure represented by Formula 3-1 are an alkoxy group, the organic semiconductor A of the hole transport layer interacts with a compound semiconductor containing an Ag element and a Bi element, thereby easily standing perpendicularly to the quantum dots of the photoelectric conversion layer. It is presumed that as a result of adopting such a structure, charge transportability is reduced or defects easily occur at the interface between the photoelectric conversion layer and the hole transport layer.

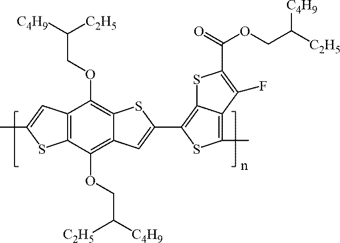

On the other hand, in the present invention, an organic semiconductor including a structure represented by Formula 3-1, in which at least one of R¹ or R² has a predetermined substituent other than the alkoxy group, is used among the organic semiconductors A that are used for the hole transport layer. It is presumed that the interaction between the organic semiconductor A having such a structure and the quantum dots of the compound semiconductor containing an Ag element and a Bi element, where the compound semiconductor is contained in the photoelectric conversion layer, is small, and the organic semiconductor A in the hole transport layer is easy to come into surface contact with the quantum dots of the photoelectric conversion layer. It is presumed that high charge transportability is obtained by adopting the structure in which the organic semiconductor A in the hole transport layer comes into surface contact with the quantum dots of the photoelectric conversion layer. In addition, it is presumed that since the organic semiconductor A having a structure represented by Formula 3-1 has a high affinity to a compound semiconductor containing an Ag element and a Bi element, and furthermore, the organic semiconductor A is easy to come into surface contact with the quantum dots of the photoelectric conversion layer, it is possible to suppress the occurrence of defects at the interface between the photoelectric conversion layer and the hole transport layer. It is presumed that the leak current can be reduced by suppressing the defects at the interface between the two, and as a result, the dark current can be reduced.

In addition, regarding the structures represented by Formulae 3-2 to 3-5 in the organic semiconductor A, it is presumed that since the planar structural portion thereof is larger than that of the structure represented by Formula 3-1, the organic semiconductor A is easy to come into surface contact with a compound semiconductor containing an Ag element and a Bi element. In addition, it is presumed that the affinity to the compound semiconductor containing an Ag element and a Bi element is also high, and the occurrence of defects at the interface between the photoelectric conversion layer and the hole transport layer can be further suppressed.

For these reasons, it is presumed that the photodetection element according to the embodiment of the present invention can have a high external quantum efficiency and low dark current.

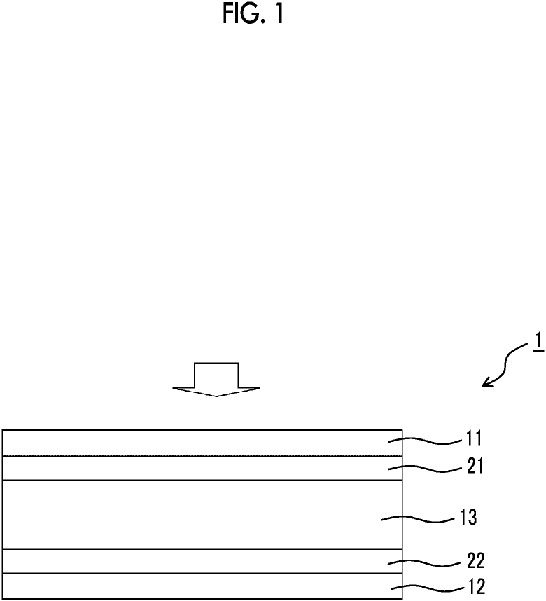

Hereinafter, the details of the photodetection element of the present invention will be described with reference to FIG. 1. FIG. 1 is a view illustrating an embodiment of a photodiode-type photodetection element. It is noted that an arrow in the figure represents the incidence ray on the photodetection element. A photodetection element 1 illustrated in FIG. 1 includes a second electrode layer 12, a first electrode layer 11 opposite to the second electrode layer 12, a photoelectric conversion layer 13 provided between the second electrode layer 12 and the first electrode layer 11, an electron transport layer 21 provided between the first electrode layer 11 and the photoelectric conversion layer 13, and a hole transport layer 22 provided between the second electrode layer 12 and the photoelectric conversion layer 13. The photodetection element 1 illustrated in FIG. 1 is used by causing light to be incident from above the first electrode layer 11. Although not illustrated in the drawing, a transparent substrate may be disposed on the surface of the first electrode layer 11 on the light incident side. Examples of the kind of transparent substrate include a glass substrate, a resin substrate, and a ceramic substrate.

### First Electrode Layer

The first electrode layer 11 is preferably a transparent electrode formed of a conductive material that is substantially transparent with respect to the wavelength of the target light to be detected by the photodetection element. It is noted that in the present invention, the description of “substantially transparent” means that the light transmittance is 50% or more, preferably 60% or more, and particularly preferably 80% or more. Examples of the material of the first electrode layer 11 include a conductive metal oxide. Specific examples thereof include tin oxide, zinc oxide, indium oxide, indium tungsten oxide, indium zinc oxide (IZO), indium tin oxide (ITO), and a fluorine-topped tin oxide (FTO).

The film thickness of the first electrode layer 11 is not particularly limited, and it is preferably 0.01 to 100 µm, more preferably 0.01 to 10 µm, and particularly preferably 0.01 to 1 µm. It is noted that in the present invention, the film thickness of each layer can be measured by observing the cross section of the photodetection element 1 using a scanning electron microscope (SEM) or the like.

### Electron Transport Layer

As illustrated in FIG. 1, the electron transport layer 21 is provided between the first electrode layer 11 and the photoelectric conversion layer 13. The electron transport layer 21 is a layer having a function of transporting electrons generated in the photoelectric conversion layer 13 to the electrode layer. The electron transport layer is also called a hole block layer. The electron transport layer is formed of an electron transport material capable of exhibiting this function. Examples of the electron transport material include a fullerene compound such as [6,6]-phenyl-C61-butyric acid methyl ester (PC₆₁BM), a perylene compound such as perylenetetracarboxylic diimide, tetracyanoquinodimethane, titanium oxide, tin oxide, zinc oxide, indium oxide, indium tungsten oxide, indium zinc oxide, indium tin oxide, and fluorine-topped tin oxide. In addition, in a case where the electron transport material is an inorganic material, the energy level and the electron transport transportability can be adjusted by further carrying out doping with another element. The electron transport layer may be a single-layer film or a laminated film having two or more layers. The thickness of the electron transport layer is preferably 10 to 1,000 nm. The upper limit thereof is preferably 800 nm or less. The lower limit thereof is preferably 20 nm or more and more preferably 50 nm or more. In addition, the thickness of the electron transport layer is preferably 0.05 to 10 times, more preferably 0.1 to 5 times, and still more preferably 0.2 to 2 times the thickness of the photoelectric conversion layer 13.

### Photoelectric Conversion Layer

A photoelectric conversion layer 13 contains quantum dots of a compound semiconductor containing an Ag (silver) element and a Bi (bismuth) element. It is noted that the compound semiconductor is a semiconductor composed of two or more kinds of elements. As a result, in the present specification, “the compound semiconductor containing an Ag element and a Bi element” is a compound semiconductor containing an Ag element and a Bi element as elements constituting the compound semiconductor. In addition, in the present specification, the “semiconductor” means a substance having a specific resistance value of 10⁻² Ωcm or more and 10⁸ Ωcm or less.

The compound semiconductor, which is a quantum dot material constituting the quantum dot, is preferably a compound semiconductor further containing at least one element selected from an S (sulfur) element or a Te (tellurium) element. According to this aspect, it is easy to obtain a photoelectric conversion film having a high external quantum efficiency with respect to light having a wavelength in the infrared region. Among the above, the compound semiconductor is preferably a compound semiconductor containing an Ag element, a Bi element, and an S element (hereinafter, also referred to as an Ag-Bi-S-based semiconductor), or a compound semiconductor containing an Ag element, a Bi element, a Te element, and an S element (hereinafter, also referred to as an Ag-Bi-Te-S-based semiconductor). Further, in the Ag-Bi-Te-S-based system semiconductor, a value obtained by dividing the number of Te elements by the total of the number of Te elements and the number of S elements ((the number of Te elements)/(the number of Te elements + the number of S elements)) is preferably 0.05 to 0.5. The lower limit thereof is preferably 0.1 or more, more preferably 0.15 or more, and still more preferably 0.2 or more. The upper limit thereof is preferably 0.45 or less and more preferably 0.4 or less. In the present specification, the kinds and the number of individual elements constituting the compound semiconductor can be measured by inductively coupled plasma (ICP) emission spectroscopy or energy dispersive X-ray spectroscopy.

The crystal structure of the compound semiconductor is not particularly limited. Various crystal structures can be adopted depending on the kind of the element constituting the compound semiconductor and the composition ratio of the element. However, due to the reason that it is easy to properly control a band gap as a semiconductor and it is easy to realize high crystallinity, a crystal structure of a cubic system or hexagonal system is preferable. In the present specification, the crystal structure of the compound semiconductor can be measured by an X-ray diffraction method or an electron beam diffraction method.

The band gap of the quantum dot of the compound semiconductor is preferably 1.2 eV or less and more preferably 1.0 eV or less. The lower limit value of the band gap of the quantum dot of the compound semiconductor is not particularly limited; however, it is preferably 0.3 eV or more and more preferably 0.5 eV or more.

The average particle diameter of the quantum dots of the compound semiconductor is preferably 3 to 20 nm. The lower limit value of the average particle diameter of the quantum dots of the compound semiconductor is preferably 4 nm or more and more preferably 5 nm or more. The upper limit value of the average particle diameter of the quantum dots of the compound semiconductor is preferably 15 nm or less and more preferably 10 nm or less. In a case where the average particle diameter of the quantum dots of the compound semiconductor is in the above range, it is possible for the photodetection element to have a higher external quantum efficiency with respect to light having a wavelength in the infrared region. It is noted that in the present specification, the value of the average particle diameter of the quantum dots is an average value of the particle diameters often quantum dots which are randomly selected. A transmission electron microscope may be used for measuring the particle diameter of the quantum dots.

It is preferable that the photoelectric conversion layer 13 contains a ligand that is coordinated to the quantum dots of the compound semiconductor. Examples of the ligand include a ligand containing a halogen atom and a polydentate ligand containing two or more coordination moieties. The photoelectric conversion layer 13 may contain only one kind of ligand or may contain two or more kinds of ligands. Among the above, the photoelectric conversion layer 13 preferably contains a ligand containing a halogen atom and a polydentate ligand. According to this aspect, it is possible for the photodetection element to have a low dark current and have excellent performance such as electrical conductivity, a photocurrent value, an external quantum efficiency, and an in-plane uniformity of external quantum efficiency. It is presumed that the reason why such effects are obtained is as follows. It is presumed that the polydentate ligand is subjected to chelate coordination to the quantum dot, and thus it is presumed that the peeling of the ligand from the quantum dot can be suppressed more effectively. In addition, it is presumed that steric hindrance between quantum dots can be suppressed by chelate coordination. For this reason, it is conceived that the steric hindrance between the quantum dots is reduced, and thus the quantum dots are closely arranged to strengthen the overlap of the wave functions between the quantum dots. Furthermore, in a case where a ligand containing a halogen atom is further contained as the ligand that is coordinated to the quantum dots, it is presumed that the ligand containing a halogen atom is coordinated in the gap where the polydentate ligand is not coordinated, and thus it is presumed that the surface defects of the quantum dot can be reduced. As a result, it is presumed that it is possible for the photodetection element to have a low dark current and have excellent performance such as electrical conductivity, a photocurrent value, an external quantum efficiency, and an in-plane uniformity of external quantum efficiency.

First, the ligand containing a halogen atom will be described. Examples of the halogen atom contained in the ligand include a fluorine atom, a chlorine atom, a bromine atom, and an iodine atom, and an iodine atom is preferable from the viewpoint of coordinating power.

The ligand containing a halogen atom may be an organic halide or may be an inorganic halide. Among the above, an inorganic halide is preferable due to the reason that it is easily coordinated to both the cation site and the anion site of the quantum dot. In a case where an inorganic halide is used, an effect of being coordinated to both the cation site and the anion site of the quantum dot can be expected. In a case where an inorganic halide is used, it is preferably a compound containing a metal element selected from a Zn (zinc) atom, an In (indium) atom, and a Cd (cadmium) atom, and it is more preferably a compound containing a Zn atom. The inorganic halide is preferably a salt of a metal atom and a halogen atom due to the reason that the salt is easily ionized and easily coordinated to the quantum dot.

Specific examples of the ligand containing a halogen atom include zinc iodide, zinc bromide, zinc chloride, indium iodide, indium bromide, indium chloride, cadmium iodide, cadmium bromide, and cadmium chloride, gallium iodide, gallium bromide, gallium chloride, tetrabutylammonium iodide, and tetramethylammonium iodide.

It is noted that in the ligand containing a halogen atom, the halogen ion may be dissociated from the ligand described above, and the halogen ion may be coordinated on the surface of the quantum dot. In addition, a portion of the ligand other than the halogen atom described above may also be coordinated on the surface of the quantum dot. To give a description with a specific example, in the case of zinc iodide, zinc iodide may be coordinated on the surface of the quantum dot, or the iodine ion or the zinc ion may be coordinated on the surface of the quantum dot.

Next, the polydentate ligand will be described. Examples of the coordination moiety contained in the polydentate ligand include a thiol group, an amino group, a hydroxy group, a carboxy group, a sulfo group, a phospho group, and a phosphonate group.

Examples of the polydentate ligand include a ligand represented by any of Formulae (A) to (C).

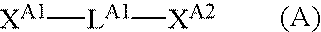

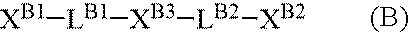

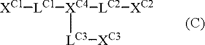

In Formula (A), X^{A1} and X^{A2} each independently represent a thiol group, an amino group, a hydroxy group, a carboxy group, a sulfo group, a phospho group, or a phosphonate group. L^{A1} represents a hydrocarbon group.

In Formula (B), X^{B1} and X^{B2} each independently represent a thiol group, an amino group, a hydroxy group, a carboxy group, a sulfo group, a phospho group, or a phosphonate group.
X^{B3} represents S, O, or NH.
L^{B1} and L^{B2} each independently represent a hydrocarbon group.

In Formula (C), X^{C1} to X^{C3} each independently represent a thiol group, an amino group, a hydroxy group, a carboxy group, a sulfo group, a phospho group, or a phosphonate group.
X^{C4} represents N.
L^{C1} to L^{C3} each independently represent a hydrocarbon group.

The amino group represented by X^{A1}, X^{A2}, X^{B1}, X^{B2}, X^{C1}, X^{C2}, or X^{C3} is not limited to —NH₂ and includes a substituted amino group and a cyclic amino group as well. Examples of the substituted amino group include a monoalkylamino group, a dialkylamino group, a monoarylamino group, a diarylamino group, and an alkylarylamino group. The amino group represented by these groups is preferably —NH₂, a monoalkylamino group, or a dialkylamino group, and more preferably —NH₂.

The hydrocarbon group represented by L^{A1}, L^{B1}, L^{B2}, L^{C1}, L^{C2}, or L^{C3} is preferably an aliphatic hydrocarbon group. The aliphatic hydrocarbon group may be a saturated aliphatic hydrocarbon group or may be an unsaturated aliphatic hydrocarbon group. The hydrocarbon group preferably has 1 to 20 carbon atoms. The upper limit of the number of carbon atoms is preferably 10 or less, more preferably 6 or less, and still more preferably 3 or less. Specific examples of the hydrocarbon group include an alkylene group, an alkenylene group, and an alkynylene group.

Examples of the alkylene group include a linear alkylene group, a branched alkylene group, and a cyclic alkylene group. A linear alkylene group or a branched alkylene group is preferable, and a linear alkylene group is more preferable. Examples of the alkenylene group include a linear alkenylene group, a branched alkenylene group, and a cyclic alkenylene group. A linear alkenylene group or a branched alkenylene group is preferable, and a linear alkenylene group is more preferable. Examples of the alkynylene group include a linear alkynylene group and a branched alkynylene group, and a linear alkynylene group is preferable. The alkylene group, the alkenylene group, and the alkynylene group may further have a substituent. The substituent is preferably a group having 1 or more and 10 or less of atoms. Preferred specific examples of the group having 1 or more and 10 or less of atoms include an alkyl group having 1 to 3 carbon atoms [a methyl group, an ethyl group, a propyl group, or an isopropyl group], an alkenyl group having 2 or 3 carbon atoms [an ethenyl group or a propenyl group], an alkynyl group having 2 to 4 carbon atoms [an ethynyl group, a propynyl group, or the like], a cyclopropyl group, an alkoxy group having 1 or 2 carbon atoms [a methoxy group or an ethoxy group], an acyl group having 2 or 3 carbon atoms [an acetyl group or a propionyl group], an alkoxycarbonyl group having 2 or 3 carbon atoms [a methoxycarbonyl group or an ethoxycarbonyl group], an acyloxy group having 2 carbon atoms [an acetyloxy group], an acylamino group having 2 carbon atoms [an acetylamino group], a hydroxyalkyl group having 1 to 3 carbon atoms [a hydroxymethyl group, a hydroxyethyl group, or a hydroxypropyl group], an aldehyde group, a hydroxy group, a carboxy group, a sulfo group, a phospho group, a carbamoyl group, a cyano group, an isocyanate group, a thiol group, a nitro group, a nitroxy group, an isothiocyanate group, a cyanate group, a thiocyanate group, an acetoxy group, an acetamide group, a formyl group, a formyloxy group, a formamide group, a sulfamino group, a sulfino group, a sulfamoyl group, a phosphono group, an acetyl group, a halogen atom, and an alkali metal atom.

In Formula (A), X^{A1} and X^{A2} are separated by L^{A1} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms.

In Formula (B), X^{B1} and X^{B3} are separated by L^{B1} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms. In addition, X^{B2} and X^{B3} are separated by L^{B2} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms.

In Formula (C), X^{C1} and X^{C4} are separated by L^{C1} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms. In addition, X^{C2} and X^{C4} are separated by L^{C2} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms. In addition, X^{C3} and X^{C4} are separated by L^{C3} preferably by 1 to 10 atoms, more preferably separated by 1 to 6 atoms, still more preferably separated by 1 to 4 atoms, even still more preferably separated by 1 to 3 atoms, and particularly preferably separated by 1 or 2 atoms.

It is noted that the description that X^{A1} and X^{A2} are separated by L^{A1} by 1 to 10 atoms means that the number of atoms constituting a molecular chain having the shortest distance, connecting X^{A1} and X^{A2}, is 1 to 10 atoms. For example, in a case of Formula (A1), X^{A1} and X^{A2} are separated by two atoms, and in cases of Formulae (A2) and (A3), X^{A1} and X^{A2} are separated by 3 atoms. The numbers added to the following structural formulae represent the arrangement order of atoms constituting a molecular chain having the shortest distance, connecting X^{A1} and X^{A2}.

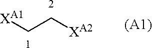

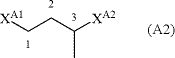

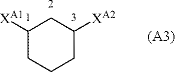

To give a description with a specific compound, 3-mercaptopropionic acid is a compound (a compound having the following structure) having a structure in which a portion corresponding to X^{A1} is a carboxy group, a portion corresponding to X^{A2} is a thiol group, and a portion corresponding to L^{A1} is an ethylene group. In 3-mercaptopropionic acid, X^{A1} (the carboxy group) and X^{A2} (the thiol group) are separated by L^{A1} (the ethylene group) by two atoms.

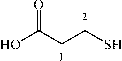

The same applies to the meanings that X^{B1} and X^{B3} are separated by L^{B1} by 1 to 10 atoms, X^{B2} and X^{B3} are separated by L^{B2} by 1 to 10 atoms, X^{C1} and X^{C4} are separated by L^{C1} by 1 to 10 atoms, X^{C2} and X^{C4} are separated by L^{C2} by 1 to 10 atoms, and X^{C3} and X^{C4} are separated by L^{C3} by 1 to 10 atoms.

Specific examples of the polydentate ligand include 3-mercaptopropionic acid, thioglycolic acid, 2-aminoethanol, 2-aminoethanethiol, 2-mercaptoethanol, glycolic acid, ethylene glycol, ethylenediamine, aminosulfonic acid, glycine, aminomethyl phosphoric acid, guanidine, diethylenetriamine, tris(2-aminoethyl)amine, 4-mercaptobutanoic acid, 3-aminopropanol, 3-mercaptopropanol, N-(3-aminopropyl)-1,3-propanediamine, 3-(bis(3-aminopropyl)amino)propane-1-ol,1-thioglycerol, dimercaprol, 1-mercapto-2-butanol, 1-mercapto-2-pentanol, 3-mercapto-1-propanol, 2,3-dimercapto-1-propanol, diethanolamine, 2-(2-aminoethyl)aminoethanol, dimethylenetriamine, 1,1-oxybismethylamine, 1,1-thiobismethylamine, 2-[(2-aminoethyl)amino]ethanethiol, bis(2-mercaptoethyl)amine, 2-aminoethane-1-thiol, 1-amino-2-butanol, 1-amino-2-pentanol, L-cysteine, D-cysteine, 3-amino-1-propanol, L-homoserine, D-homoserine, aminohydroxyacetic acid, L-lactic acid, D-lactic acid, L-malic acid, D-malic acid, glyceric acid, 2-hydroxybutyric acid, L-tartaric acid, D-tartaric acid, tartronic acid, and derivatives thereof. Due to the reason that a semiconductor film has a low dark current and a high external quantum efficiency, the polydentate ligand is preferably thioglycolic acid, 2-aminoethanol, 2-aminoethanethiol, 2-mercaptoethanol, glycolic acid, diethylenetriamine, tris(2-aminoethyl)amine, 1-thioglycerol, dimercaprol, ethylenediamine, ethylene glycol, aminosulfonic acid, glycine, (aminomethyl)phosphonic acid, guanidine, diethanolamine, 2-(2-aminoethyl)aminoethanol, homoserine, cysteine, thiomalic acid, malic acid, or tartaric acid, more preferably thioglycolic acid, 2-aminoethanol, 2-mercaptoethanol, or 2-aminoethanethiol, and still more preferably thioglycolic acid.

The thickness of the photoelectric conversion layer 13 is preferably 10 to 1,000 nm. The lower limit of the thickness is preferably 20 nm or more and more preferably 30 nm or more. The upper limit of the thickness is preferably 600 nm or less, more preferably 550 nm or less, still more preferably 500 nm or less, and particularly preferably 450 nm or less.

The refractive index of the photoelectric conversion layer 13 with respect to light having a target wavelength to be detected by the photodetection element can be set to 1.5 to 5.0.

The photoelectric conversion layer 13 can be formed by undergoing a step (a quantum dot aggregate forming step) of applying a dispersion liquid containing quantum dots of a compound semiconductor containing an Ag element and a Bi element, a ligand that is coordinated to the quantum dots, and a solvent onto a substrate to form a film of aggregate of the quantum dots.

The method of applying a quantum dot dispersion liquid onto a substrate is not particularly limited. Examples thereof include coating methods such as a spin coating method, a dipping method, an ink jet method, a dispenser method, a screen printing method, a relief printing method, an intaglio printing method, and a spray coating method.

The film thickness of the film of aggregates of the quantum dots, formed by the quantum dot aggregate forming step, is preferably 3 nm or more, more preferably 10 nm or more, and still more preferably 20 nm or more. The upper limit thereof is preferably 200 nm or less, more preferably 150 nm or less, and still more preferably 100 nm or less.

After forming a film of the aggregate of quantum dots, a ligand exchange step may be further carried out to exchange the ligand coordinated to the quantum dot with another ligand. In the ligand exchange step, a ligand solution containing a ligand (hereinafter, also referred to as a ligand A) different from the ligand contained in the above-described dispersion liquid and containing a solvent is applied onto the film of the aggregate of quantum dots, the aggregate being formed by the quantum dot aggregate forming step, to exchange the ligand coordinated to the quantum dots with the ligand A contained in the ligand solution. In addition, the quantum dot aggregate forming step and the ligand exchange step may be alternately repeated a plurality of times.

Examples of the ligand A include a ligand containing a halogen atom and a polydentate ligand containing two or more coordination moieties. Examples of the details thereof include those described in the section of the photoelectric conversion film described above, and the same applies to the preferred range thereof.

The ligand solution that is used in the ligand exchange step may contain only one kind of the ligand A or may contain two or more kinds thereof. In addition, two or more kinds of ligand solutions may be used.

The solvent contained in the ligand solution is preferably selected appropriately according to the kind of the ligand contained in each ligand solution, and it is preferably a solvent that easily dissolves each ligand. In addition, the solvent contained in the ligand solution is preferably an organic solvent having a high dielectric constant. Specific examples thereof include ethanol, acetone, methanol, acetonitrile, dimethylformamide, dimethyl sulfoxide, butanol, and propanol. In addition, the solvent contained in the ligand solution is preferably a solvent that does not easily remain in the formed photoelectric conversion film. From the viewpoints of easy drying and easy removal by washing, a low boiling point alcohol, a ketone, or a nitrile is preferable, and methanol, ethanol, acetone, or acetonitrile is more preferable. The solvent contained in the ligand solution is preferably one that does not mix with the solvent contained in the quantum dot dispersion liquid. Regarding the preferred solvent combination, in a case where the solvent contained in the quantum dot dispersion liquid is an alkane such as hexane or octane or toluene, it is preferable to use a polar solvent such as methanol or acetone as the solvent contained in the ligand solution.

A step (a rinsing step) of bringing a rinsing liquid into contact with a film after the ligand exchange step to rinse the film may be carried out. In a case where the rinsing step is carried out, it is possible to remove the excess ligand contained in the film and the ligand released from the quantum dots. In addition, it is possible to remove the remaining solvent and other impurities. The rinsing liquid is preferably an aprotic solvent due to the reason that it is easier to effectively remove excess ligands contained in the film and ligands released from the quantum dots, and it is easy to keep the film surface shape uniform by rearranging the surface of the quantum dots. Specific examples of the aprotic solvent include acetonitrile, acetone, methyl ethyl ketone, methyl isobutyl ketone, cyclopentanone, diethyl ether, tetrahydrofuran, cyclopentyl methyl ether, dioxane, ethyl acetate, butyl acetate, propylene glycol monomethyl ether acetate, hexane, octane, cyclohexane, benzene, toluene, chloroform, carbon tetrachloride, and dimethylformamide, where acetonitrile or tetrahydrofuran is preferable, and acetonitrile is more preferable.

In addition, the rinsing step may be carried out a plurality of times by using two or more kinds of rinsing liquids differing in polarity (relative permittivity). For example, it is preferable that, first, a rinsing liquid (also referred to as a first rinsing liquid) having a high relative permittivity is used to carry out rinsing, and then a rinsing liquid (also referred to as a second rinsing liquid) having a relative permittivity lower than that of the first rinsing liquid is used to carry out rinsing. In a case of rinsing in this way, it is possible to first remove the excess component of the ligand A used in the ligand exchange, and then remove the released ligand component (the component that has been originally coordinated to the particles) generated in the ligand exchange process, and it is possible to more efficiently remove both the excess or the released ligand component.

The relative permittivity of the first rinsing liquid is preferably 15 to 50, more preferably 20 to 45, and still more preferably 25 to 40. The relative permittivity of the second rinsing liquid is preferably 1 to 15, more preferably 1 to 10, and still more preferably 1 to 5.

The manufacturing method for a photoelectric conversion film may include a drying step. In a case of carrying out the drying step, it is possible to remove the solvent remaining on the photoelectric conversion film. The drying time is preferably 1 to 100 hours, more preferably 1 to 50 hours, and still more preferably 5 to 30 hours. The drying temperature is preferably 10° C. to 100° C., more preferably 20° C. to 90° C., and still more preferably 20° C. to 50° C.

### Hole Transport Layer

As illustrated in FIG. 1, the hole transport layer 22 is provided between the second electrode layer 12 and the photoelectric conversion layer 13. The hole transport layer is a layer having a function of transporting holes generated in the photoelectric conversion layer to the electrode layer. The hole transport layer is also called an electron block layer. In the photodetection element according to the embodiment of the present invention, it is preferable that the hole transport layer 22 is disposed on the surface of the photoelectric conversion layer 13.

The hole transport layer 22 in the photodetection element of the present invention contains an organic semiconductor including a structure represented by any one of Formulae 3-1 to 3-5 (hereinafter, the organic semiconductor including a structure represented by any one of Formulae 3-1 to 3-5 is also described as the organic semiconductor A).

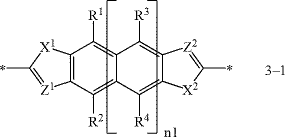

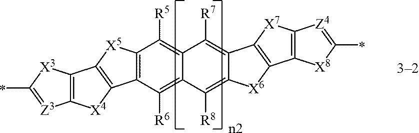

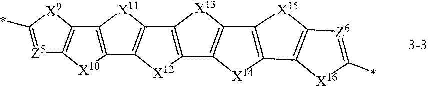

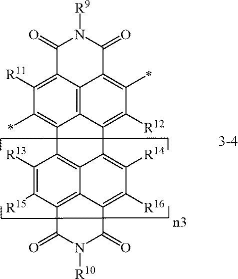

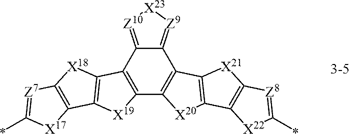

In Formula 3-1, X¹ and X² each independently represent S, O, Se, NR^{X1}, or CR^{X2}R^{X3}, where R^{X1} to R^{X3} each independently represent a hydrogen atom or a substituent,
Z¹ and Z² each independently represent N or CR^{Z1}, where R^{Z1} represents a hydrogen atom or a substituent,
R¹ to R⁴ each independently represent a hydrogen atom or a substituent,
n1 represents an integer of 0 to 2, and
* represents a bonding site.

However, at least one of R¹ or R² represents a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, a group represented by Formula (R-100), or a group including an intramolecular salt structure.

-L¹⁰⁰-R¹⁰⁰ ^{...}(R-100)

In (R, L¹⁰⁰ represents a single bond or a divalent group, and R¹⁰⁰ represents an acid group, a basic group, a group having an anion, or a group having a cation.

In Formula 3-2, X³ to X⁸ each independently represent S, O, Se, NR^{X4}, or CR^{X5}R^{X6}, where R^{X4} to R^{X6} each independently represent a hydrogen atom or a substituent,
Z³ and Z⁴ each independently represent N or CR^{Z2}, where R^{Z2} represents a hydrogen atom or a substituent,
R⁵ to R⁸ each independently represent a hydrogen atom or a substituent,
n2 represents an integer of 0 to 2, and
* represents a bonding site.

In Formula 3-3, X⁹ to X¹⁶ each independently represent S, O, Se, NR^{X7}, or CR^{X8}R^{X9}, where R^{X7} to R^{X9} each independently represent a hydrogen atom or a substituent,
Z⁵ and Z⁶ each independently represent N or CR^{Z3}, where R^{Z3} represents a hydrogen atom or a substituent, and
* represents a bonding site.

In Formula 3-4, R⁹ to R¹⁶ each independently represent a hydrogen atom or a substituent,
n3 represents an integer of 0 to 2, and
* represents a bonding site.

In Formula 3-5, X¹⁷ to X²³ each independently represent S, O, Se, NR^{X10}, or CR^{X11}R^{X12},
where R^{X10} to R^{X12} each independently represent a hydrogen atom or a substituent,
Z⁷ to Z¹⁰ each independently represent N or CR^{Z4}, where R^{Z4} represents a hydrogen atom or a substituent, and
* represents a bonding site.

### About Formula 3-1

X¹ and X² of Formula 3-1 each independently represent S, O, Se, NR^{X1}, or CR^{X2}R^{X3}, where R^{X1} to R^{X3} each independently represent a hydrogen atom or a substituent. Examples of the substituent represented by R^{X1} to R^{X3} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, and an alkyl group, an aryl group, or a heteroaryl group is more preferable. In addition, the alkyl group, the aryl group, and the heteroaryl group may further have a substituent. Examples of the substituent which may be further contained include a substituent T described later.

X¹ and X² of Formula 3-1 are each independently preferably S, NR^{X1}, or CR^{X2}R^{X3}, more preferably S or NR^{X1}, and still more preferably S.

Z¹ and Z² of Formula 3-1 each independently represent N or CR^{Z1}, where R^{Z1} represents a hydrogen atom or a substituent. Examples of the substituent represented by R^{Z1} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, an alkyl group, an aryl group, or a heteroaryl group is more preferable, and an alkyl group is still more preferable. In addition, the alkyl group, the aryl group, and the heteroaryl group may further have a substituent. Examples of the substituent which may be further contained include a substituent T described later.

Z¹ and Z² of Formula 3-1 are each independently preferably CR^{Z1}.

R¹ to R⁴ of Formula 3-1 each independently represent a hydrogen atom or a substituent. Examples of the substituent represented by R^{X1} to R^{X3} include a substituent T described later, the group represented by Formula (R-100) described above, and a group including an intramolecular salt structure. However, at least one of R¹ or R² represents a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, a group represented by Formula (R-100), or a group including an intramolecular salt structure.

At least one of R¹ or R² is preferably a heteroaryl group, a group represented by Formula (R-100), or a group including an intramolecular salt structure, and more preferably a group represented by Formula (R-100) or a group including an intramolecular salt structure.

In addition, R¹ and R² are each independently preferably a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, a group represented by Formula (R-100), or a group including an intramolecular salt structure, more preferably a heteroaryl group, a group represented by Formula (R-100), or a group including an intramolecular salt structure, and still more preferably a group represented by Formula (R-100) or a group including an intramolecular salt structure.

The group represented by Formula (R-100) will be described.

Examples of the divalent group represented by L¹⁰⁰ in Formula (R-100) include an alkylene group, an arylene group, a heteroarylene group, —O—, —CO—, —COO—, —OCO—, —NH—, and —S—, as well as a group in which two or more kinds of these are combined. The alkylene group preferably has 1 to 15 carbon atoms, more preferably 1 to 10 carbon atoms, and still more preferably 1 to 5 carbon atoms. The alkylene group may be linear, branched, or cyclic, and it is preferably linear or cyclic. The arylene group preferably has 6 to 50 carbon atoms, more preferably 6 to 30 carbon atoms, and still more preferably 6 to 12 carbon atoms. The arylene group may be a monocyclic ring or may be a group obtained by fusing two or more rings. The number of heteroatoms that constitute a ring of the heterocyclic group is preferably 1 to 3. The heteroatom that constitutes a ring of the heterocyclic group is preferably a nitrogen atom, an oxygen atom, or a sulfur atom. The number of carbon atoms that constitutes a ring of the heterocyclic group is preferably 1 to 20, more preferably 1 to 15, and still more preferably 1 to 12. The heterocyclic group may be a monocyclic ring or may be a group obtained by fusing two or more rings. The heterocyclic group may be a non-aromatic heterocyclic ring or may be an aromatic heterocyclic ring. The alkylene group, the arylene group, and the heterocyclic group may have a substituent. Examples of the substituent include a substituent T described later.

R¹⁰⁰ represents an acid group, a basic group, a group having an anion, or a group having a cation.

Examples of the acid group include a carboxy group, a sulfo group, a phosphate group, a group represented by -SO₂NHSO₂Rf¹, or salts thereof. Rf¹ in the group represented by -SO₂NHSO₂Rf¹ represents a group containing a fluorine atom. Examples of the group containing a fluorine atom, represented by Rf¹, include a fluorine atom, an alkyl group containing a fluorine atom, and an aryl group containing a fluorine atom, where an alkyl group containing a fluorine atom is preferable. The alkyl group containing a fluorine atom preferably has 1 to 10 carbon atoms, more preferably 1 to 5 carbon atoms, and still more preferably 1 to 3 carbon atoms. The aryl group containing a fluorine atom preferably has 6 to 20 carbon atoms, more preferably 6 to 12 carbon atoms, and still more preferably 6 carbon atoms. Examples of the atom or atomic group constituting the salt include an alkali metal ion (Li⁺, Na⁺, K⁺, or the like), an alkaline earth metal ion (Ca²⁺, Mg²⁺, or the like), and an ammonium cation.

Examples of the basic group include a salt of an amino group and an ammonium group, where a salt of an ammonium group is preferable. Examples of the atom or atomic group constituting the salt in the salt of the ammonium group salt include a hydroxide ion, a halogen ion, a carboxylate ion, a sulfonate ion, and a phenoxide ion.

Examples of the amino group include a group represented by -NRx¹Rx² and a cyclic amino group. In the group represented by NRx¹Rx², Rx¹ and Rx² each independently represent a hydrogen atom, an alkyl group, or an aryl group. The alkyl group preferably has 1 to 10 carbon atoms, more preferably 1 to 5 carbon atoms, and still more preferably 1 to 3 carbon atoms. The alkyl group may be linear, branched, or cyclic, and it is preferably linear or branched and more preferably linear. The alkyl group may have a substituent. Examples of the substituent include a substituent T described later. The aryl group preferably has 6 to 30 carbon atoms, more preferably 6 to 20 carbon atoms, and still more preferably 6 to 12 carbon atoms. The alkyl group may have a substituent. Examples of the substituent include a substituent T described later.

Examples of the cyclic amino group include a pyrrolidine group, a piperidine group, a piperazine group, and a morpholine group. These groups may have a substituent.

Examples of the group having an anion include a carboxylate group, a sulfonate group, a phosphate group, a phosphonate group, a phosphinate group, and a sulfonimide anion group.

Examples of the group having a cation include an ammonium cation group, a phosphonium cation group, a pyrrolidinium group, a piperidinium group, a piperazinium group, and a morpholinium group.

Next, a group including an intramolecular salt structure will be described. The group including an intramolecular salt structure means a group including a structure in which a group having a cation and a group having an anion are bonded through a covalent bond. The intramolecular salt structure is also called a zwitterionic structure. The group including an intramolecular salt structure is preferably a group represented by Formula A-1.

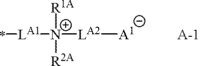

In Formula A-1, L^{A1} represents a divalent linking group, L^{A2} represents a single bond or a divalent linking group, A¹ represents a group having an anion, R^{1A} and R^{2A} each independently represent a hydrogen atom or a substituent, and * represents a bonding site.

Examples of the substituent represented by R^{1A} and R^{2A} include a substituent T described later, where an alkyl group, an aryl group, or a heteroaryl group is preferable, and an alkyl group is more preferable. In addition, the alkyl group, the aryl group, and the heteroaryl group may further have a substituent. Examples of the substituent which may be further contained include a substituent T described later.

Examples of the divalent linking group represented by L^{A1} and the divalent linking group represented by L^{A2} include an alkylene group, an arylene group, a heteroarylene group, —O—, —CO—, —COO—, —OCO—, —NH—, and —S—, as well as a group in which two or more kinds of these are combined. The alkylene group preferably has 1 to 15 carbon atoms, more preferably 1 to 10 carbon atoms, and still more preferably 1 to 5 carbon atoms. The alkylene group may be linear, branched, or cyclic, and it is preferably linear or cyclic. The arylene group preferably has 6 to 50 carbon atoms, more preferably 6 to 30 carbon atoms, and still more preferably 6 to 12 carbon atoms. The arylene group may be a monocyclic ring or may be a group obtained by fusing two or more rings. The number of heteroatoms that constitute a ring of the heterocyclic group is preferably 1 to 3. The heteroatom that constitutes a ring of the heterocyclic group is preferably a nitrogen atom, an oxygen atom, or a sulfur atom. The number of carbon atoms that constitutes a ring of the heterocyclic group is preferably 1 to 20, more preferably 1 to 15, and still more preferably 1 to 12. The heterocyclic group may be a monocyclic ring or may be a group obtained by fusing two or more rings. The heterocyclic group may be a non-aromatic heterocyclic ring or may be an aromatic heterocyclic ring. The alkylene group, the arylene group, and the heterocyclic group may have a substituent. Examples of the substituent include a substituent T described later.

Examples of the group having an anion, represented by A¹, include a carboxylate group, a sulfonate group, a phosphate group, a phosphonate group, a phosphinate group, and a sulfonimide anion group.

n1 of Formula 3-1 represents an integer of 0 to 2, and it is preferably 0 or 1 and more preferably 0. In a case where n1 of Formula 3-1 is 0, Formula 3-1 has the structure shown below.

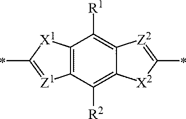

### - About Formula 3-2 -

X³ to X⁸ of Formula 3-2 each independently represent S, O, Se, NR^{X4}, or CR^{X5}R^{X6}, where R^{X4} to R^{X6} each independently represent a hydrogen atom or a substituent. Examples of the substituent represented by R^{X4} to R^{X6} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, and an alkyl group, an aryl group, or a heteroaryl group is more preferable. In addition, the alkyl group, the aryl group, and the heteroaryl group may further have a substituent. Examples of the substituent which may be further contained include a substituent T described later.

X³ to X⁸ of Formula 3-2 are each independently preferably S, NR^{X4}, or CR^{X5}R^{X6}. In addition, at least one of X³, ..., or X⁸ is preferably S or NR^{X4}, and more preferably S.

Z³ and Z⁴ of Formula 3-2 each independently represent N or CR^{Z2}, where R^{Z2} represents a hydrogen atom or a substituent. Examples of the substituent represented by R^{Z2} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, an alkyl group, an aryl group, or a heteroaryl group is more preferable, and an alkyl group is still more preferable. In addition, the alkyl group, the aryl group, and the heteroaryl group may further have a substituent. Examples of the substituent which may be further contained include a substituent T described later.

Z³ and Z⁴ of Formula 3-2 are each independently preferably CR^{Z2}.

R⁵ to R⁸ of Formula 3-2 each independently represent a hydrogen atom or a substituent. Examples of the substituent represented by R⁵ to R⁸ include a substituent T described later, a group represented by Formula (R-100), and a group including an intramolecular salt structure. At least one of R⁵ or R⁶ is preferably a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an alkoxy group, an aryloxy group, an alkylthio group, an arylthio group, a heteroaryl group, a group represented by Formula (R-100), or a group including an intramolecular salt structure, more preferably a heteroaryl group, a group represented by Formula (R-100), or a group including an intramolecular salt structure, and still more preferably a group represented by Formula (R-100) or a group including an intramolecular salt structure.

n2 of Formula 3-2 represents an integer of 0 to 2, and it is preferably 0 or 1 and more preferably 0. In a case where n2 of Formula 3-2 is 0, Formula 3-2 has the structure shown below.

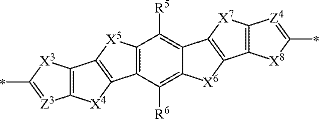

### - About Formula 3-3 -

X⁹ to X¹⁶ of Formula 3-3 each independently represent S, O, Se, NR^{X7}, or CR^{X8}R^{X9}, where R^{X7} to R^{X9} each independently represent a hydrogen atom or a substituent. Examples of the substituent represented by R^{X7} to R^{X9} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, and an alkyl group, an aryl group, or a heteroaryl group is more preferable. In addition, the alkyl group, the aryl group, and the heteroaryl group may further have a substituent. Examples of the substituent which may be further contained include a substituent T described later.

X⁹ to X¹⁶ of Formula 3-3 are each independently preferably S, NR^{X7}, or CR^{X8}R^{X9}. In addition, at least one of X⁹, ..., or X¹⁶ is preferably S or NR^{X7}, and more preferably S.

Z⁵ and Z⁶ of Formula 3-3 each independently represent N or CR^{Z3}, where R^{Z3} represents a hydrogen atom or a substituent. Examples of the substituent represented by R^{Z3} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, an alkyl group, an aryl group, or a heteroaryl group is more preferable, and an alkyl group is still more preferable. In addition, the alkyl group, the aryl group, and the heteroaryl group may further have a substituent. Examples of the substituent which may be further contained include a substituent T described later.

Z⁵ and Z⁶ of Formula 3-3 are each independently preferably CR^{Z3}.

### - About Formula 3-4 -

R⁹ to R¹⁶ of Formula 3-4 each independently represent a hydrogen atom or a substituent. Examples of the substituent represented by R⁹ to R¹⁶ include a substituent T described later, a group represented by Formula (R-100), and a group including an intramolecular salt structure.

At least one of R⁹, ..., or R¹² is preferably a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an alkoxy group, an aryloxy group, an alkylthio group, an arylthio group, a heteroaryl group, a group represented by Formula (R-100), or a group including an intramolecular salt structure, more preferably a heteroaryl group, a group represented by Formula (R-100), or a group including an intramolecular salt structure, and still more preferably a group represented by Formula (R-100) or a group including an intramolecular salt structure.

In a case where n3 of Formula 3-4 is 1 or 2, at least one of R⁹, ..., or R¹⁶ is preferably a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an alkoxy group, an aryloxy group, an alkylthio group, an arylthio group, a heteroaryl group, a group represented by Formula (R-100), or a group including an intramolecular salt structure, more preferably a heteroaryl group, a group represented by Formula (R-100), or a group including an intramolecular salt structure, and still more preferably a group represented by Formula (R-100) or a group including an intramolecular salt structure.

n3 of Formula 3-4 represents an integer of 0 to 2, and it is preferably 0 or 1 and more preferably 0. In a case where n3 of Formula 3-4 is 0, Formula 3-4 has the structure shown below.

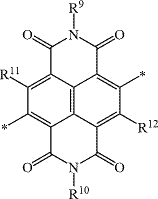

### - About Formula 3-5 -

X¹⁷ to X²³ of Formula 3-5 each independently represent S, O, Se, NR^{X10}, or CR^{X11}R^{X12}, where R^{X10} to R^{X12} each independently represent a hydrogen atom or a substituent. Examples of the substituent represented by R^{X10} to R^{X12} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, and an alkyl group, an aryl group, or a heteroaryl group is more preferable. In addition, the alkyl group, the aryl group, and the heteroaryl group may further have a substituent. Examples of the substituent which may be further contained include a substituent T described later.

X¹⁷ to X²³ of Formula 3-5 are each independently preferably S, NR^{X10}, or CR^{X11}R^{X12}, and more preferably S or NR^{X10}. X¹⁷, X¹⁸, X²¹, X²², and X²³ are particularly preferably S. X¹⁹ and X²⁰ are each independently preferably S or NR^{X10}.

Z⁷ to Z¹⁰ of Formula 3-5 each independently represent N or CR^{Z4}, where R^{Z4} represents a hydrogen atom or a substituent. Examples of the substituent represented by R^{Z4} include a substituent T described later, a group represented by Formula (R-100), and a group including an intramolecular salt structure, where an alkyl group, an aryl group, a heteroaryl group, a group represented by Formula (R-100), or a group including an intramolecular salt structure is preferable, an alkyl group, an aryl group, or a heteroaryl group is more preferable, and an alkyl group is still more preferable. In addition, the alkyl group, the aryl group, and the heteroaryl group may further have a substituent. Examples of the substituent which may be further contained include a substituent T described later.

Z⁷ and Z⁸ of Formula 3-5 are each independently preferably CR^{Z4}. In addition, Z⁹ and Z¹⁰ of Formula 3-5 are preferably N.

### - Substituent T -

Examples of the substituent T include a heavy hydrogen, an alkyl group, an alkenyl group, an alkynyl group, an aryl group, a heteroaryl group, an alkoxy group, an aryloxy group, an alkylthio group, an arylthio group, an amino group, an acyl group, an acyloxy group, an acylamino group, an alkoxycarbonyl group, an aryloxycarbonyl group, a sulfonamide group, a carbamoyl group, a sulfamoyl group, a halogen atom, a nitrile group, an isonitrile group, a hydroxy group, an alkylsulfinyl group, an arylsulfinyl group, an alkylsulfonyl group, an arylsulfonyl group, a phosphino group, a cyano group, a silyl group, a carboxy group, and a sulfo group.

The alkyl group preferably has 1 to 20 carbon atoms, more preferably 1 to 15 carbon atoms, and still more preferably 1 to 10 carbon atoms. The alkyl group may be linear, branched, or cyclic.

The alkenyl group preferably has 2 to 20 carbon atoms, more preferably 2 to 15 carbon atoms, and still more preferably 2 to 10 carbon atoms. The alkenyl group may be linear, branched, or cyclic.

The alkynyl group preferably has 2 to 20 carbon atoms, more preferably 2 to 15 carbon atoms, and still more preferably 2 to 10 carbon atoms. The alkynyl group may be linear or branched.

The aryl group preferably has 6 to 50 carbon atoms, more preferably 6 to 30 carbon atoms, and still more preferably 6 to 12 carbon atoms. The aryl group may be a monocyclic ring or may be a group obtained by fusing two or more rings.

The number of heteroatoms constituting the ring of the heteroaryl group is preferably 1 to 3. The heteroatom constituting the ring of the heteroaryl group is preferably a nitrogen atom, an oxygen atom, or a sulfur atom. The number of carbon atoms constituting the ring in the heteroaryl group is preferably 1 to 20, more preferably 1 to 15, and more preferably 1 to 12. The heteroaryl group may be a monocyclic ring or may be a group obtained by fusing two or more rings.

The alkoxy group preferably has 1 to 20 carbon atoms, more preferably 1 to 15 carbon atoms, and still more preferably 1 to 10 carbon atoms. The alkoxy group may be linear or branched.

The aryloxy group preferably has 6 to 50 carbon atoms, more preferably 6 to 30 carbon atoms, and still more preferably 6 to 12 carbon atoms. The aryl moiety of the aryloxy group may be a monocyclic ring or may be a group obtained by fusing two or more rings.

The alkylthio group preferably has 1 to 20 carbon atoms, more preferably 1 to 15 carbon atoms, and still more preferably 1 to 10 carbon atoms. The alkylthio group may be linear or branched.

The arylthio group preferably has 6 to 50 carbon atoms, more preferably 6 to 30 carbon atoms, and still more preferably 6 to 12 carbon atoms. The aryl moiety of the arylthio group may be a monocyclic ring or may be a group obtained by fusing two or more rings.

Examples of the amino group include a group represented by -NRx¹Rx² and a cyclic amino group. Examples of the cyclic amino group include a pyrrolidine group, a piperidine group, a piperazine group, and a morpholine group. In the group represented by NRx¹Rx², Rx¹ and Rx² each independently represent a hydrogen atom, an alkyl group, or an aryl group. The alkyl group preferably has 1 to 10 carbon atoms, more preferably 1 to 5 carbon atoms, and still more preferably 1 to 3 carbon atoms. The alkyl group may be linear, branched, or cyclic, and it is preferably linear or branched and more preferably linear. The aryl group preferably has 6 to 30 carbon atoms, more preferably 6 to 20 carbon atoms, and still more preferably 6 to 12 carbon atoms.

The acyl group, the acyloxy group, and the acylamino group preferably have 2 to 50 carbon atoms, more preferably 2 to 30 carbon atoms, and still more preferably 2 to 12 carbon atoms.

The alkoxycarbonyl group preferably has 2 to 20 carbon atoms, more preferably 2 to 15 carbon atoms, and still more preferably 2 to 10 carbon atoms. The alkoxycarbonyl group may be linear or branched.

The aryloxycarbonyl group preferably has 7 to 50 carbon atoms, more preferably 7 to 30 carbon atoms, and still more preferably 7 to 12 carbon atoms. The aryl moiety of the aryloxycarbonyl group may be a monocyclic ring or may be a group obtained by fusing two or more rings.

The sulfonamide group preferably has 1 to 50 carbon atoms, more preferably 1 to 30 carbon atoms, and still more preferably 1 to 12 carbon atoms.

The carbamoyl group preferably has 1 to 50 carbon atoms, more preferably 1 to 30 carbon atoms, and still more preferably 1 to 12 carbon atoms.

The sulfamoyl group preferably has 1 to 50 carbon atoms, more preferably 1 to 30 carbon atoms, and still more preferably 1 to 12 carbon atoms.

Examples of the halogen atom include a chlorine atom, a bromine atom, an iodine atom, and a fluorine atom.

The alkylsulfinyl group preferably has 1 to 20 carbon atoms, more preferably 1 to 15 carbon atoms, and still more preferably 1 to 10 carbon atoms.

The arylsulfinyl group preferably has 6 to 50 carbon atoms, more preferably 6 to 30 carbon atoms, and still more preferably 6 to 12 carbon atoms.

The alkylsulfonyl group preferably has 1 to 20 carbon atoms, more preferably 1 to 15 carbon atoms, and still more preferably 1 to 10 carbon atoms.

The arylsulfonyl group preferably has 6 to 50 carbon atoms, more preferably 6 to 30 carbon atoms, and still more preferably 6 to 12 carbon atoms.

The phosphino group preferably has 0 to 30 carbon atoms. Specific examples of the phosphino group include a dimethylphosphino group, a diphenylphosphino group, and a methylphenoxyphosphino group.

The silyl group is preferably a group represented by -SiR^{si1}R^{si2}R^{si3}. R^{si1} to R^{si3} each independently represent an alkyl group or an aryl group, and they are preferably an alkyl group. The alkyl group preferably has 1 to 10 carbon atoms, more preferably 1 to 5 carbon atoms, and still more preferably 1 to 3 carbon atoms. The alkyl group may be linear, branched, or cyclic, and it is preferably linear or branched and more preferably linear. The aryl group preferably has 6 to 50 carbon atoms, more preferably 6 to 30 carbon atoms, and still more preferably 6 to 12 carbon atoms. The aryl group may be a monocyclic ring or may be a group obtained by fusing two or more rings. Specific examples of the silyl group include a trimethylsilyl group, a t-butyldimethylsilyl group, and a phenyldimethylsilyl group.

### Preferred Aspect of Organic Semiconductor A

Due to the reason that a photodetection element having a high external quantum efficiency and a reduced dark current can be obtained, the organic semiconductor A is preferably a compound including a structure represented by Formula 3-1 or a compound including a structure represented by Formula 3-4, and more preferably a compound including a structure represented by Formula 3-1.

The organic semiconductor A preferably further includes a structure represented by Formula 4. That is, the organic semiconductor A is preferably a compound that further contains a structure represented by Formula 4, in addition to the structure represented by any one of Formulae 3-1 to 3-5 described above. In addition, the organic semiconductor A is more preferably a compound that contains the structure represented by Formula 3-1 described above and a structure represented by Formula 4. In a case of using the organic semiconductor A having such a structure in the hole transport layer, the organic semiconductor A in the hole transport layer is easy to come into surface contact with the quantum dots of the photoelectric conversion layer, whereby a higher external quantum efficiency can be obtained. Further, it is possible to further suppress the occurrence of defects at the interface between the photoelectric conversion layer and the hole transport layer, and it is also possible to further reduce the dark current.

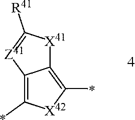

X⁴¹ and X⁴² of Formula 4 each independently represent S, O, Se, NR^{X41}, or CR^{X42}R^{X43}, where R^{X41} to R^{X43} each independently represent a hydrogen atom or a substituent. Examples of the substituent represented by R^{X41} to R^{X43} include the substituent T described above, a group represented by Formula (R-100), and a group including an intramolecular salt structure, where an electron withdrawing group is preferable, and a halogen atom is more preferable.

X⁴¹ and X⁴² of Formula 4 are each independently preferably S, O, Se, or NR^{X41}, and more preferably S.

Z⁴¹ of Formula 4 represents N or CR^{Z41}, where R^{Z41} represents a hydrogen atom or a substituent. Z⁴¹ is preferably CR^{Z3}. Examples of the substituent represented by R^{Z41} include the substituent T described above, a group represented by Formula (R-100), and a group including an intramolecular salt structure, where an electron withdrawing group is preferable, and a halogen atom is more preferable.

R⁴¹ of Formula 4 represents a hydrogen atom or a substituent. Examples of the substituent represented by R⁴¹ include the substituent T, the group represented by Formula (R-100), and the group including an intramolecular salt structure, which are described above, where a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an alkoxy group, an aryloxy group, an alkylthio group, an arylthio group, a heteroaryl group, a group represented by Formula (R-100), or a group including an intramolecular salt structure is preferable, and an acyl group, an acyloxy group, an alkoxycarbonyl group, or an aryloxycarbonyl group is more preferable.

### * Of Formula 4 Represents a Bonding Site

The organic semiconductor A is preferably a compound having a group represented by Formula (R-100) or a group having an intramolecular salt structure. The organic semiconductor A containing this group has a high affinity to the quantum dots of the compound semiconductor containing an Ag element and a Bi element, where the compound semiconductor is contained in the photoelectric conversion layer, and the organic semiconductor A in the hole transport layer is easy to come into surface contact with the quantum dots of the photoelectric conversion layer, whereby a higher external quantum efficiency can be obtained. Further, it is possible to further suppress the occurrence of defects at the interface between the photoelectric conversion layer and the hole transport layer, and it is also possible to further reduce the dark current.

The organic semiconductor A is preferably a compound including a structure represented by Formula 5.

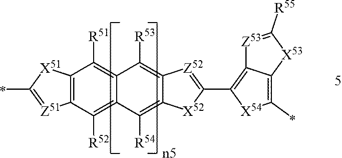

In Formula 5, X⁵¹ to X⁵⁴ each independently represent S, O, Se, NR^{X51}, or CR^{X52}R^{X53},
where R^{X51} to R^{X53} each independently represent a hydrogen atom or a substituent,
Z⁵¹ to Z⁵³ each independently represent N or CR^{Z51}, where R^{Z51} represents a hydrogen atom or a substituent,
R⁵¹ to R⁵⁵ each independently represent a hydrogen atom or a substituent,
n5 represents an integer of 0 to 2, and
* represents a bonding site.

However, at least one of R⁵¹ or R⁵² represents a halogen atom, a hydroxy group, a cyano group, an amino group, an acylamino group, an acyloxy group, a carboxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, a group represented by Formula (R-100), or a group including an intramolecular salt structure.

X⁵¹ and X⁵² of Formula 5 have the same meaning as X¹ and X² of Formula 3-1, respectively.
X⁵³ and X⁵⁴ of Formula 5 have the same meaning as X⁴¹ and X⁴² of Formula 4, respectively.
Z⁵¹ and Z⁵² of Formula 5 have the same meaning as Z¹ and Z² of Formula 3-1, respectively.
Z⁵¹ of Formula 5 has the same meaning as Z⁴¹ of Formula 4.
R⁵¹ to R⁵⁴ of Formula 5 have the same meaning as R¹ to R⁴ of Formula 3-1, respectively.
R⁵⁵ of Formula 5 has the same meaning as R⁴¹ of Formula 4.
n5 in Formula 5 has the same meaning as n1 in Formula 3-1.

At least one of R⁵¹ or R⁵² in Formula 5 is preferably a heteroaryl group, a group represented by Formula (R-100), or a group including an intramolecular salt structure, and more preferably a group represented by Formula (R-100) or a group including an intramolecular salt structure.

In addition, R⁵¹ and R⁵² are each independently preferably a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, a group represented by Formula (R-100), or a group including an intramolecular salt structure, more preferably a heteroaryl group, a group represented by Formula (R-100), or a group including an intramolecular salt structure, and still more preferably a group represented by Formula (R-100) or a group including an intramolecular salt structure.

It is noted that in a case where n5 of Formula 5 is 0, Formula 5 has the structure shown below.

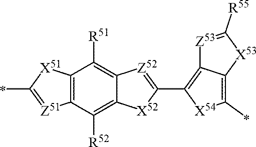

The organic semiconductor A is preferably a polymer. In a case where the organic semiconductor A is a polymer, the weight-average molecular weight thereof is preferably 3,000 to 500,000, more preferably 10,000 to 300,000, and still more preferably 15,000 to 250,000. In addition, the number-average molecular weight thereof is preferably 2,000 to 400,000, more preferably 10,000 to 300,000, and still more preferably 20,000 to 200,000.

### Specific Example of Organic Semiconductor A

Among the organic semiconductors A that are used for the hole transport layer 22, specific examples of the compound including a structure represented by Formula 3-1 include a compound having the following structure.

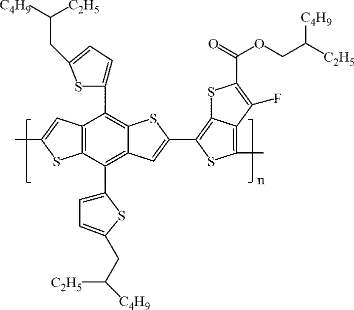

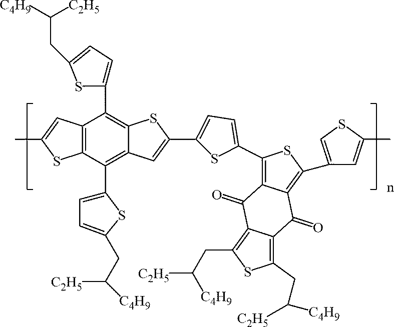

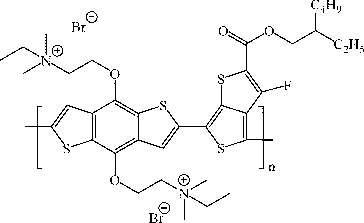

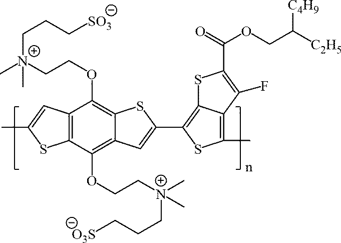

In addition, among the organic semiconductors A that are used for the hole transport layer 22, specific examples of the compound including a structure represented by Formula 3-2 include a compound having a structure shown below.

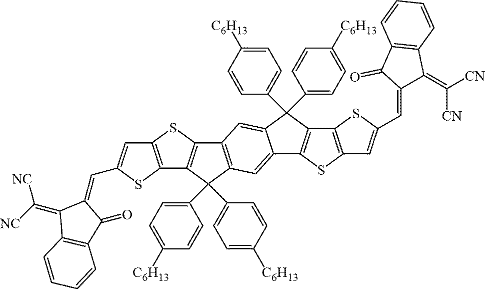

In addition, among the organic semiconductors A that are used for the hole transport layer 22, specific examples of the compound including a structure represented by Formula 3-3 include a compound having a structure shown below.

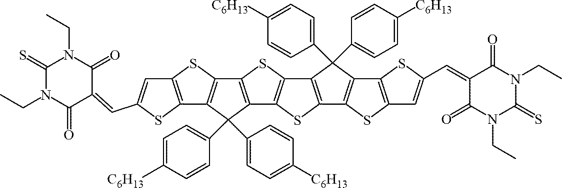

In addition, among the organic semiconductors A that are used for the hole transport layer 22, specific examples of the compound including a structure represented by Formula 3-4 include a compound having a structure shown below.

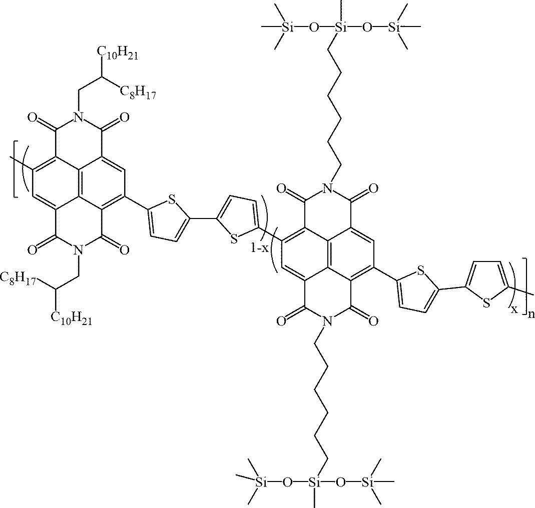

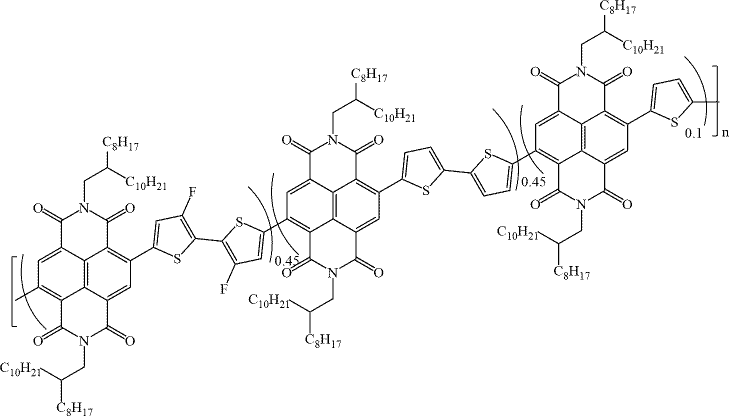

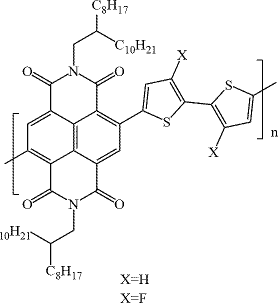

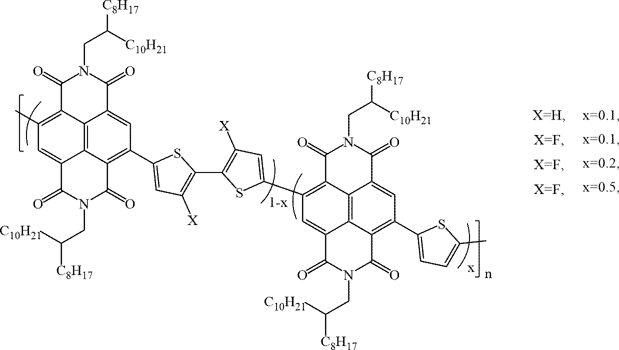

In addition, among the organic semiconductors A that are used for the hole transport layer 22, specific examples of the compound including a structure represented by Formula 3-5 include a compound having a structure shown below.

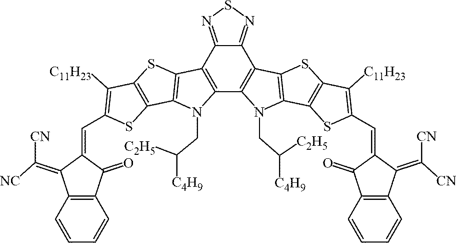

### Preferred Aspect of Hole Transport Layer

The hole transport layer may contain only one kind of the above-described organic semiconductor A or may contain two or more kinds thereof. In a case of containing two or more kinds of the organic semiconductors A, it is possible for the photodetection element to have a higher external quantum efficiency and have a further reduced dark current. Although the detailed reason therefor is unknown, it is presumed that in a case of using two or more kinds of the organic semiconductors A in combination, defects at the interface between the hole transport layer and the photoelectric conversion layer can be further suppressed and the leak current can be further reduced.

In addition, in a case where two or more kinds of organic semiconductors A are contained, the following aspects (1) to (10) can be included, where the aspect of (1) or (6) is preferable.
(1) Aspect including two or more kinds of compounds including a structure represented by Formula 3-1
(2) Aspect including two or more kinds of compounds including a structure represented by Formula 3-2
(3) Aspect including two or more kinds of compounds including a structure represented by Formula 3-3
(4) Aspect including two or more kinds of compounds including a structure represented by Formula 3-4
(5) Aspect including two or more kinds of compounds including a structure represented by Formula 3-5
(6) Aspect including at least one compound including a structure represented by Formula 3-1 and at least one compound including a structure represented by any one of Formula 3-2, Formula 3-3, Formula 3-4, or Formula 3-5
(7) Aspect including at least one compound including a structure represented by Formula 3-2 and at least one compound including a structure represented by any one of Formula 3-1, Formula 3-3, Formula 3-4, or Formula 3-5
(8) Aspect including at least one compound including a structure represented by Formula 3-3 and at least one compound including a structure represented by any one of Formula 3-1, Formula 3-2, Formula 3-4, or Formula 3-5
(9) Aspect including at least one compound including a structure represented by Formula 3-4 and at least one compound including a structure represented by any one of Formula 3-1, Formula 3-2, Formula 3-3, or Formula 3-5
(10) Aspect including at least one compound including a structure represented by Formula 3-5 and at least one compound including a structure represented by any one of Formula 3-1, Formula 3-2, Formula 3-3, or Formula 3-4

In addition, it is also preferable that the hole transport layer further contains an organic semiconductor (hereinafter, also referred to as the organic semiconductor) other than the organic semiconductor A, in addition to the organic semiconductor A. With this aspect as well, it is possible for the photodetection element to have a higher external quantum efficiency and have a further reduced dark current. In this aspect, only one kind or two or more kinds of each of the organic semiconductor A and the other organic semiconductor may be contained.

The other organic semiconductor is preferably an n-type semiconductor. Specific examples of other organic semiconductor include a fullerene-based organic semiconductor such as [6,6]-phenyl-C61-methyl butyrate (PC₆₁BM) or [6,6]-phenyl-C71-methyl butyrate (PC₇₁BM), and a non-fullerene-based organic semiconductor such as a compound having the following structures, where a fullerene-based organic semiconductor is preferable.

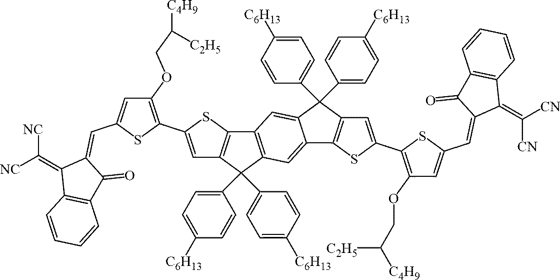

In a case where the hole transport layer contains the other organic semiconductor, the content of the other organic semiconductor is preferably 1 to 99 parts by mass, more preferably 10 to 90 parts by mass, and still more preferably 20 to 80 parts by mass, with respect to 100 parts by mass of the organic semiconductor A.

The thickness of the hole transport layer containing the organic semiconductor A is preferably 5 to 100 nm. The lower limit thereof is preferably 10 nm or more. The upper limit thereof is preferably 50 nm or less and more preferably 30 nm or less.

### Another Hole Transport Layer

The photodetection element according to the present invention may further include, in addition to the above-described hole transport layer containing the organic semiconductor A, another hole transport layer composed of a hole transport material different from that of the organic semiconductor A. Examples of the hole transport material that constitutes the other hole transport layer include poly(3,4-ethylenedioxythiophene):poly(4-styrenesulfonic acid) (PEDOT:PSS) and MoO₃. In addition, a quantum dot can also be used in the hole transport material. Examples of the quantum dot material that constitutes the quantum dot include a nano particle (a particle having a size of 0.5 nm or more and less than 100 nm) of a general semiconductor crystal [a) a Group IV semiconductor, b) a compound semiconductor of a Group IV to IV element, a Group III to V element, or a Group II to VI element, or c) a compound semiconductor consisting of a combination of three or more of a Group II element, a Group III element, a Group IV element, a Group V element, and a Group VI element]. Specific examples thereof include semiconductor materials having a relatively narrow band gap, such as PbS, PbSe, PbSeS, InN, InAs, Ge, InGaAs, CuInS, CuInSe, CuInGaSe, InSb, HgTe, HgCdTe, Ag₂S, Ag₂Se, Ag₂Te, SnS, SnSe, SnTe, Si, and InP. A ligand may be coordinated on the surface of the quantum dot.

In a case where the photodetection element of the embodiment of the present invention includes the other hole transport layer, it is preferable that the hole transport layer containing the organic semiconductor A is disposed on the side of the photoelectric conversion layer 13.

The thickness of the other hole transport layer is preferably 5 to 100 nm. The lower limit thereof is preferably 10 nm or more. The upper limit thereof is preferably 50 nm or less and more preferably 30 nm or less.

### Second Electrode Layer

The second electrode layer 12 is preferably composed of a metal material containing at least one metal atom selected from Au, Pt, Ir, Pd, Cu, Pb, Sn, Zn, Ti, W, Mo, Ta, Ge, Ni, Cr, or In. Since the second electrode layer 12 is composed of such a metal material, it is possible for the photodetection element to have a high external quantum efficiency and have a low dark current.

The second electrode layer 12 is more preferably composed of a metal material containing at least one metal atom selected from Au, Cu, Mo, Ni, Pd, W, Ir, Pt, or Ta, and due to the reason that the work function is large and the migration is easily suppressed, it is still more preferably composed of a metal material containing at least one metal atom selected from Au, Pd, Ir, or Pt.

In the second electrode layer 12, the content of the Ag atom is preferably 98% by mass or less, more preferably 95% by mass or less, and still more preferably 90% by mass or less. Further, it is also preferable that the second electrode layer 12 contains substantially no Ag atoms. The case where the second electrode layer 12 contains substantially no Ag atoms means that the content of the Ag atom in the second electrode layer 12 is 1% by mass or less, where it is preferable that the content thereof is 0.1% by mass or less, and it is more preferable that the second electrode layer 12 contains substantially no Ag atoms.

The work function of the second electrode layer 12 is preferably 4.6 eV or more, more preferably 4.8 to 5.7 eV, and still more preferably 4.9 to 5.3 eV, due to the reason that the electron blocking property due to the hole transport layer is increased and the holes generated in the element are easily collected.

The film thickness of the second electrode layer 12 is not particularly limited, and it is preferably 0.01 to 100 µm, more preferably 0.01 to 10 µm, and particularly preferably 0.01 to 1 µm.

### Blocking Layer

Although not illustrated in the drawing, the photodetection element of the embodiment of the present invention may have a blocking layer between the first electrode layer 11 and the electron transport layer 21. The blocking layer is a layer having a function of preventing a reverse current. The blocking layer is also called a short circuit prevention layer. Examples of the material that forms the blocking layer include silicon oxide, magnesium oxide, aluminum oxide, calcium carbonate, cesium carbonate, polyvinyl alcohol, polyurethane, titanium oxide, tin oxide, zinc oxide, niobium oxide, and tungsten oxide. The blocking layer may be a single-layer film or a laminated film having two or more layers.

### Characteristics of Photodetection Element

In the photodetection element of the embodiment of the present invention, a wavelength λ of the target light to be detected by the photodetection element and an optical path length L^{λ} of the light having the wavelength λ from the surface of the second electrode layer 12 on the side of the photoelectric conversion layer 13 to the surface of the photoelectric conversion layer 13 on the side of the first electrode layer 11 preferably satisfy the relationship of Formula (1-1), and more preferably satisfy the relationship of Formula (1-2). In a case where the wavelength λ and the optical path length L^{λ} satisfy such a relationship, in the photoelectric conversion layer 13, it is possible to arrange phases of the light (the incidence ray) incident from the side of the first electrode layer 11 and phases of the light (the reflected light) reflected on the surface of the second electrode layer 12, and as a result, the light is intensified by the optical interference effect, whereby it is possible to obtain a higher external quantum efficiency.

$$0.05 + \text{m} / 2 \leq {\text{L}}^{λ} / λ \leq 0.35 + \text{m} / 2 \qquad \text{(1-1)}$$

$$0.10 + \text{m} / 2 \leq {\text{L}}^{λ} / λ \leq 0.30 + \text{m} / 2 \qquad \text{(1-2)}$$

In the above expressions, λ is the wavelength of the target light to be detected by the photodetection element,
L^{λ} is the optical path length of the light having the wavelength λ from a surface of the second electrode layer 12 on a side of the photoelectric conversion layer 13 to a surface of the photoelectric conversion layer 13 on a side of the first electrode layer 11, and
m is an integer of 0 or more.

m is preferably an integer of 0 to 4, more preferably an integer of 0 to 3, and still more preferably an integer of 0 to 2. According to this aspect, the transport characteristics of charges such as the hole and the electron are good, and thus it is possible to increase the external quantum efficiency of the photodetection element.

Here, the optical path length means the product obtained by multiplying the physical thickness of a substance through which light transmits by the refractive index. To give a description with the photoelectric conversion layer 13 as an example, in a case where the thickness of the photoelectric conversion layer is denoted by d¹ and the refractive index of the photoelectric conversion layer with respect to the wavelength λ¹ is denoted by N¹, the optical path length of the light having a wavelength λ¹ and transmitting through the photoelectric conversion layer 13 is N¹ × d¹. In a case where the photoelectric conversion layer 13 or the hole transport layer 22 is composed of two or more laminated films or in a case where an interlayer is present between the hole transport layer 22 and the second electrode layer 12, the integrated value of the optical path length of each layer is the optical path length L^{λ}.

The photodetection element according to the embodiment of the present invention is preferably used as an element that detects light having a wavelength in the infrared region. That is, the photodetection element according to the embodiment of the present invention is preferably an infrared photodetection element. In addition, the target light to be detected by the above-described photodetection element is preferably light having a wavelength in the infrared region. The light having a wavelength in the infrared region is preferably light having a wavelength of more than 700 nm, more preferably light having a wavelength of 800 nm or more, still more preferably light having a wavelength of 900 nm or more, and even still preferably light having a wavelength of 1,000 nm or more. In addition, the light having a wavelength in the infrared region is preferably light having a wavelength of 2,000 nm or less, more preferably light having a wavelength of 1,800 nm or less, and still more preferably light having a wavelength of 1,600 nm or less.

In addition, the photodetection element according to the embodiment of the present invention may simultaneously detect light having a wavelength in the infrared region and light having a wavelength in the visible region (preferably light having a wavelength in a range of 400 to 700 nm).

### Image Sensor

The image sensor according to the embodiment of the present invention includes the above-described photodetection element according to the embodiment of the present invention. Since the photodetection element according to the embodiment of the present invention has excellent sensitivity to light having a wavelength in the infrared region, it can be particularly preferably used as an infrared image sensor.

The configuration of the image sensor is not particularly limited as long as it has the photodetection element according to the embodiment of the present invention and it is a configuration that functions as an image sensor.

The image sensor invention may include an infrared transmitting filter layer. The infrared transmitting filter layer preferably has a low light transmittance in the wavelength range of the visible region, more preferably has an average light transmittance of 10% or less, still more preferably 7.5% or less, and particularly preferably 5% or less in a wavelength range of 400 to 650 nm.

Examples of the infrared transmitting filter layer include those composed of a resin film containing a coloring material. Examples of the coloring material include a chromatic coloring material such as a red coloring material, a green coloring material, a blue coloring material, a yellow coloring material, a purple coloring material, and an orange coloring material, and a black coloring material. It is preferable that the coloring material contained in the infrared transmitting filter layer forms a black color with a combination of two or more kinds of chromatic coloring materials or a coloring material containing a black coloring material. Examples of the combination of the chromatic coloring material in a case of forming a black color by a combination of two or more kinds of chromatic coloring materials include the following aspects (C1) to (C7).
(C1) an aspect containing a red coloring material and a blue coloring material.
(C2) an aspect containing a red coloring material, a blue coloring material, and a yellow coloring material.
(C3) an aspect containing a red coloring material, a blue coloring material, a yellow coloring material, and a purple coloring material.
(C4) an aspect containing a red coloring material, a blue coloring material, a yellow coloring material, a purple coloring material, and a green coloring material.
(C5) an aspect containing a red coloring material, a blue coloring material, a yellow coloring material, and a green coloring material.
(C6) an aspect containing a red coloring material, a blue coloring material, and a green coloring material.
(C7) an aspect containing a yellow coloring material and a purple coloring material.

The chromatic coloring material may be a pigment or a dye. It may contain a pigment and a dye. The black coloring material is preferably an organic black coloring material. Examples of the organic black coloring material include a bisbenzofuranone compound, an azomethine compound, a perylene compound, and an azo compound.

The infrared transmitting filter layer may further contain an infrared absorber. In a case where the infrared absorber is contained in the infrared transmitting filter layer, the wavelength of the light to be transmitted can be shifted to the longer wavelength side. Examples of the infrared absorber include a pyrrolo pyrrole compound, a cyanine compound, a squarylium compound, a phthalocyanine compound, a naphthalocyanine compound, a quaterrylene compound, a merocyanine compound, a croconium compound, an oxonol compound, an iminium compound, a dithiol compound, a triarylmethane compound, a pyrromethene compound, an azomethine compound, an anthraquinone compound, a dibenzofuranone compound, a dithiolene metal complex, a metal oxide, and a metal boride.

The spectral characteristics of the infrared transmitting filter layer can be appropriately selected according to the use application of the image sensor. Examples of the filter layer include those that satisfy any one of the following spectral characteristics of (1) to (5).
(1): A filter layer in which the maximum value of the light transmittance in the film thickness direction in a wavelength range of 400 to 750 nm is 20% or less (preferably 15% or less and more preferably 10% or less), and the minimum value of the light transmittance in the film thickness direction in a wavelength range of 900 to 1,500 nm is 70% or more (preferably 75% or more and more preferably 80% or more).
(2): A filter layer in which the maximum value of the light transmittance in the film thickness direction in a wavelength range of 400 to 830 nm is 20% or less (preferably 15% or less and more preferably 10% or less), and the minimum value of the light transmittance in the film thickness direction in a wavelength range of 1,000 to 1,500 nm is 70% or more (preferably 75% or more and more preferably 80% or more).
(3): A filter layer in which the maximum value of the light transmittance in the film thickness direction in a wavelength range of 400 to 950 nm is 20% or less (preferably 15% or less and more preferably 10% or less), and the minimum value of the light transmittance in the film thickness direction in a wavelength range of 1,100 to 1,500 nm is 70% or more (preferably 75% or more and more preferably 80% or more).
(4): A filter layer in which the maximum value of the light transmittance in the film thickness direction in a wavelength range of 400 to 1,100 nm is 20% or less (preferably 15% or less and more preferably 10% or less), and the minimum value thereof in a wavelength range of 1,400 to 1,500 nm is 70% or more (preferably 75% or more and more preferably 80% or more).
(5): A filter layer in which the maximum value of the light transmittance in the film thickness direction in a wavelength range of 400 to 1,300 nm is 20% or less (preferably 15% or less and more preferably 10% or less), and the minimum value thereof in a wavelength range of 1,600 to 2,000 nm is 70% or more (preferably 75% or more and more preferably 80% or more).

Further, in the infrared transmitting filter, the film disclosed in JP2013-077009A, JP2014-130173A, JP2014-130338A, WO2015/166779A, WO2016/178346A, WO2016/190162A, WO2018/016232A, JP2016-177079A, JP2014-130332A, or WO2016/027798A can be used. In addition, as the infrared transmitting filter, two or more filters may be used in combination, or a dual bandpass filter that transmits through two or more specific wavelength ranges with one filter may be used.

The image sensor may include an infrared shielding filter for the intended purpose of improving various performances such as noise reduction. Specific examples of the infrared shielding filter include the filters disclosed in WO2016/186050A, WO2016/035695A, JP6248945B, WO2019/021767A, JP2017-067963A, and JP6506529B.

The image sensor may include a dielectric multi-layer film. Examples of the dielectric multi-layer film include those in which a plurality of layers are laminated by alternately laminating a dielectric thin film having a high refractive index (a high refractive index material layer) and a dielectric thin film having a low refractive index (a low refractive index material layer). The number of laminated layers of the dielectric thin film in the dielectric multi-layer film is not particularly limited; however, it is preferably 2 to 100 layers, more preferably 4 to 60 layers, and still more preferably 6 to 40 layers. The material that is used for forming the high refractive index material layer is preferably a material having a refractive index of 1.7 to 2.5. Specific examples thereof include Sb₂O₃, Sb₂S₃, Bi₂O₃, CeO₂, CeFs, HfO₂, La₂O₃, Nd₂O₃, Pr₆O₁₁, Sc₂O₃, SiO, Ta₂O₅, TiO₂, TlCl, Y₂O₃, ZnSe, ZnS, and ZrO₂. The material that is used for forming the low refractive index material layer is preferably a material having a refractive index of 1.2 to 1.6. Specific examples thereof include Al₂O₃, BiF₃, CaF₂, LaF₃, PbCl₂, PbF₂, LiF, MgF₂, MgO, NdF₃, SiO₂, Si₂O₃, NaF, ThO₂, ThF₄, and Na₃AlF₆. The method for forming the dielectric multi-layer film is not particularly limited; however, examples thereof include ion plating, a vacuum deposition method using an ion beam or the like, a physical vapor deposition method (a PVD method) such as sputtering, and a chemical vapor deposition method (a CVD method). The thickness of each of the high refractive index material layer and the low refractive index material layer is preferably 0.1 λ to 0.5 λ in a case where the wavelength of the light to be blocked is λ (nm). Specific examples of the dielectric multi-layer film include the dielectric multi-layer films disclosed in JP2014-130344A and JP2018-010296A.

In the dielectric multi-layer film, the transmission wavelength range is preferably present in the infrared region (preferably a wavelength range having a wavelength of more than 700 nm, more preferably a wavelength range having a wavelength of more than 800 nm, and still more preferably a wavelength range having a wavelength of more than 900 nm). The maximum transmittance in the transmission wavelength range is preferably 70% or more, more preferably 80% or more, and still more preferably 90% or more. In addition, the maximum transmittance in the shielding wavelength range is preferably 20% or less, more preferably 10% or less, and still more preferably 5% or less. In addition, the average transmittance in the transmission wavelength range is preferably 60% or more, more preferably 70% or more, and still more preferably 80% or more. In addition, in a case where the wavelength at which the maximum transmittance is exhibited is denoted by a central wavelength λₜ₁, the wavelength range of the transmission wavelength range is preferably “the central wavelength λₜ₁ ± 100 nm”, more preferably “the central wavelength λₜ₁ ± 75 nm”, and still more preferably “the central wavelength λₜ₁ ± 50 nm”.

The dielectric multi-layer film may have only one transmission wavelength range (preferably, a transmission wavelength range having a maximum transmittance of 90% or more) or may have a plurality of transmission wavelength ranges.

The image sensor may include a color separation filter layer. Examples of the color separation filter layer include a filter layer including colored pixels. Examples of the kind of colored pixel include a red pixel, a green pixel, a blue pixel, a yellow pixel, a cyan pixel, and a magenta pixel. The color separation filter layer may include colored pixels having two or more colors or having only one color. It can be appropriately selected according to the use application and the intended purpose. As the color separation filter layer, for example, the filter disclosed in WO2019/039172A can be used.

In addition, in a case where the color separation layer includes colored pixels having two or more colors, the colored pixels of the respective colors may be adjacent to each other, or a partition wall may be provided between the respective colored pixels. The material of the partition wall is not particularly limited. Examples thereof include an organic material such as a siloxane resin or a fluororesin, and an inorganic particle such as a silica particle. In addition, the partition wall may be composed of a metal such as tungsten or aluminum.

In a case where the image sensor includes an infrared transmitting filter layer and a color separation layer, it is preferable that the color separation layer is provided on an optical path different from the infrared transmitting filter layer. In addition, it is also preferable that the infrared transmitting filter layer and the color separation layer are disposed two-dimensionally. The fact that the infrared transmitting filter layer and the color separation layer are two-dimensionally disposed means that at least a part of both is present on the same plane.

The image sensor may include an interlayer such as a planarizing layer, an underlying layer, or an intimate attachment layer, an anti-reflection film, and a lens. As the anti-reflection film, for example, a film produced from the composition disclosed in WO2019/017280A can be used. As the lens, for example, the structure disclosed in WO2018/092600A can be used.

The photodetection element according to the embodiment of the present invention has excellent sensitivity to light having a wavelength in the infrared region. As a result, the image sensor according to the embodiment of the present invention can be preferably used as an infrared image sensor. In addition, the image sensor according to the embodiment of the present invention can be preferably used as a sensor that senses light having a wavelength of 900 to 2,000 nm and can be more preferably used as a sensor that senses light having a wavelength of 900 to 1,600 nm.

### EXAMPLES

Hereinafter, the present invention will be described in detail with reference to Examples. Materials, amounts used, proportions, treatment details, treatment procedures, and the like shown in the following examples can be appropriately changed without departing from the gist of the present invention. Accordingly, a scope of the present invention is not limited to the following specific examples.

### Production of Quantum Dot Dispersion Liquid

### Quantum Dot Dispersion Liquid 1

30 ml of oleic acid, 0.8 mmol of silver acetate, and 1 mmol of bismuth acetate were weighed out in a flask and heated at 100° C. for 3 hours under vacuum to obtain a precursor solution. After putting the system in a nitrogen flow state, 1 mmol of hexamethyldisilathiane was injected into the precursor solution in the flask together with 5 mL of octadecene. Immediately after the injection, the flask was naturally cooled, and at a stage where the temperature of the solution in the flask reached 40° C., 20 mL of toluene was added thereto and the solution was recovered. An excess amount of acetone was added to the recovered solution, centrifugation was carried out at 10,000 rpm for 10 minutes, and the precipitate was dispersed in toluene to obtain a quantum dot dispersion liquid 1 in which the concentration of the AgBiS₂ quantum dots was 30 mg/mL. A quantum dot thin film was produced using the obtained quantum dot dispersion liquid 1, and a tauc plot of an indirect transition semiconductor was created from the absorption measurement of the quantum dot thin film. The band gap estimated from the tauc plot was approximately 1.1 eV.

### Quantum Dot Dispersion Liquid 2

5.4 ml of oleic acid, 0.8 mmol of silver acetate, 1 mmol of bismuth acetate, and 30 mL of octadecene were weighed out in a flask and heated at 100° C. for 3 hours under vacuum to obtain a precursor solution. After putting the system in a nitrogen flow state, 5 mL of oleylamine was added to the solution in the flask, and then 0.9 mmol of hexamethyldisilathiane and 0.1 mmol of bis(trimethylsilyl)telluride were injected together with 5 mL of octadecene. Immediately after the injection, the flask was naturally cooled, and at a stage where the temperature of the solution in the flask reached 40° C., 5 mL of trioctylphosphine and 10 mL of toluene were added thereto and the solution was recovered. An excess amount of acetone was added to the recovered solution, centrifugation was carried out at 5,000 rpm for 10 minutes, and the precipitate was dispersed in toluene to obtain a quantum dot dispersion liquid 2 in which the concentration of the AgBiSTe quantum dots was 30 mg/mL. A quantum dot thin film was produced using the obtained quantum dot dispersion liquid 2, and a tauc plot of an indirect transition semiconductor was created from the absorption measurement of the quantum dot thin film. The band gap estimated from the tauc plot was approximately 1.01 eV.

### Manufacture of Photodetection Element

### Examples 1 to 13 and Comparative Example 1

An indium tin oxide (ITO) film (the first electrode layer) having a thickness of about 100 nm was formed on quartz glass by a sputtering method.

Next, the ITO film was subjected to spin coating with a solution obtained by dissolving 1 g of zinc acetate dihydrate and 284 µl of ethanolamine in 10 ml of methoxyethanol at 3,000 rpm. Then, heating was carried out at 200° C. for 30 minutes to form a zinc oxide film (an electron transport layer) having a thickness of about 50 nm.

Next, the quantum dot dispersion liquid described in the table below was added dropwise onto the zinc oxide film, and then spin coating was carried out at 2,000 rpm to obtain a quantum dot aggregate film (a step 1).

Next, a methanol solution of tetramethylammonium iodide (concentration: 1 mg/mL) as a ligand solution was added dropwise onto the quantum dot aggregate film, and immediately, spin drying was carried out at 2,000 rpm for 20 seconds. Next, as the rinsing liquid, methanol was added dropwise onto the quantum dot aggregate film and subjected to spin drying at 2,000 rpm for 20 seconds. Next, toluene was added dropwise onto the quantum dot aggregate film and subjected to spin drying at 2,000 rpm for 20 seconds (a step 2).

The operation of the step 1 and the step 2 as one cycle was repeated for four cycles to form a photoelectric conversion layer to have a thickness of 60 nm, in which tetramethylammonium iodide as a ligand was coordinated to the AgBiS₂ quantum dots.

Next, the photoelectric conversion layer was dried at 50° C. for 10 minutes in a nitrogen atmosphere and then dried at room temperature for 10 hours under a nitrogen atmosphere and light shielding conditions.

Next, the photoelectric conversion layer was subjected to spin coating with a chlorobenzene solution containing the organic semiconductors described in the table below at the concentrations described in the table below, in a glove box at 2,000 rpm for 60 seconds, to form a hole transport layer having a thickness of about 10 nm.

Next, a MoO₃ film having a thickness of 15 nm was formed on the hole transport layer by a vacuum deposition method through a metal mask, and then an Au film (the second electrode layer) having a thickness of 100 nm was formed to manufacture a photodiode-type photodetection element.

TABLE 1

| | Kind of quantum dot dispersion liquid | Kind of organic semiconductor | Concentration of organic semiconductor (mg/mL) |
|---|---|---|---|
| Example 1 | Quantum dot dispersion liquid 1 | PTB7-Th | 10 |
| Example 2 | Quantum dot dispersion liquid 1 | PTB7-NBr | 10 |
| Example 3 | Quantum dot dispersion liquid 1 | PTB7-NSO₃ | 10 |
| Example 4 | Quantum dot dispersion liquid 1 | Compound A | 10 |
| Example 5 | Quantum dot dispersion liquid 1 | BTP | 10 |
| Example 6 | Quantum dot dispersion liquid 1 | 6TBA | 10 |
| Example 7 | Quantum dot dispersion liquid 1 | PNDI-Si50 | 10 |
| Example 8 | Quantum dot dispersion liquid 1 | PTB7-Th ITIC | 5 5 |
| Example 9 | Quantum dot dispersion liquid 1 | PTB7-Th 6TBA | 5 5 |
| Example 10 | Quantum dot dispersion liquid 1 | PTB7-Th BTP | 5 5 |
| Example 11 | Quantum dot dispersion liquid 1 | PTB7-Th PNDI-F45T10 | 5 5 |
| Example 12 | Quantum dot dispersion liquid 1 | PTB7-Th PC₆₁BM | 5 5 |
| Example 13 | Quantum dot dispersion liquid 1 | PTB7-Th PC₇₁BM | 5 5 |
| Example 14 | Quantum dot dispersion liquid 1 | PTB7-Th IEICO | 5 5 |
| Example 15 | Quantum dot dispersion liquid 2 | PTB7-Th | 10 |
| Example 16 | Quantum dot dispersion liquid 2 | PTB7-Th PC₇₁BM | 10 |
| Comparative Example 1 | Quantum dot dispersion liquid 1 | PTB7 | 5 |

Details of the organic semiconductors described by the abbreviations in the above table are as follows.

PTB7-Th: A compound having the following structure (weight-average molecular weight: about 145,000)

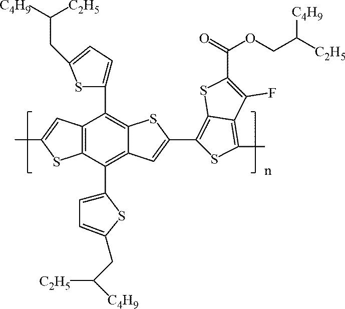

PTB7-NBr: A compound having the following structure (weight-average molecular weight: about 20,000)

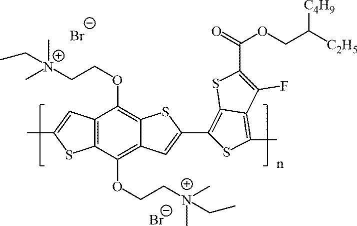

PTB7-NSO₃: A compound having the following structure (weight-average molecular weight: about 20,000)

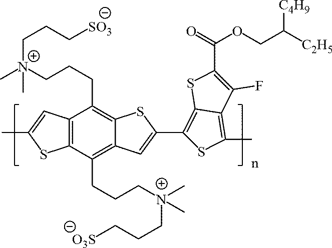

Compound A: A compound having the following structure (weight-average molecular weight: about 20,000)

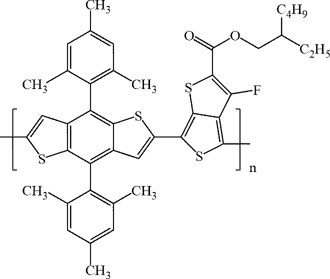

BTP: A compound having the following structure

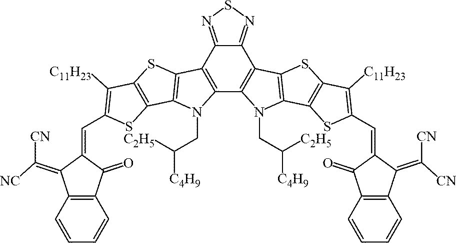

6TBA: A compound having the following structure

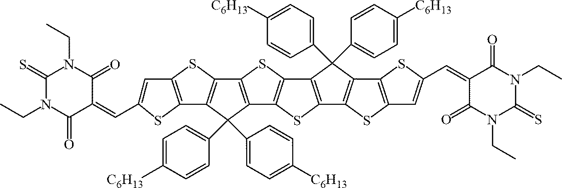

ITIC: A compound having the following structure

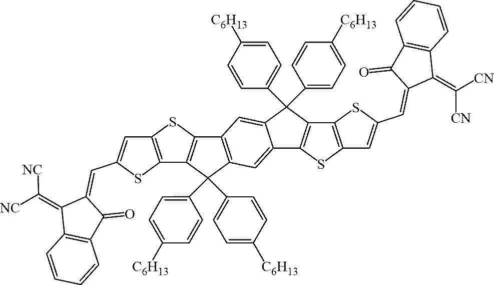

PNDI-Si50: A compound having the following structure (x = 0.5)

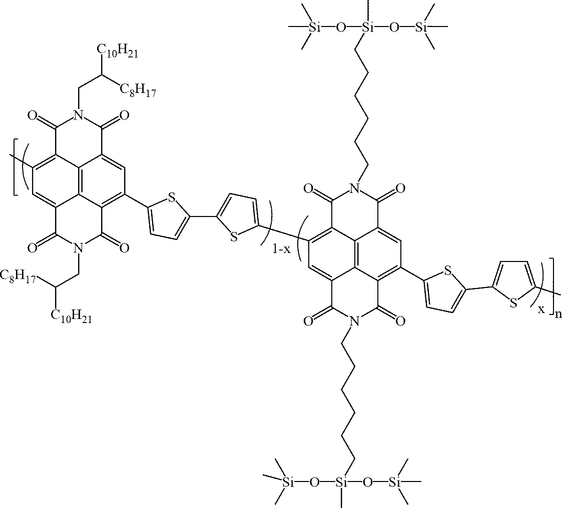

PNDI-F45T10: A compound having the following structure

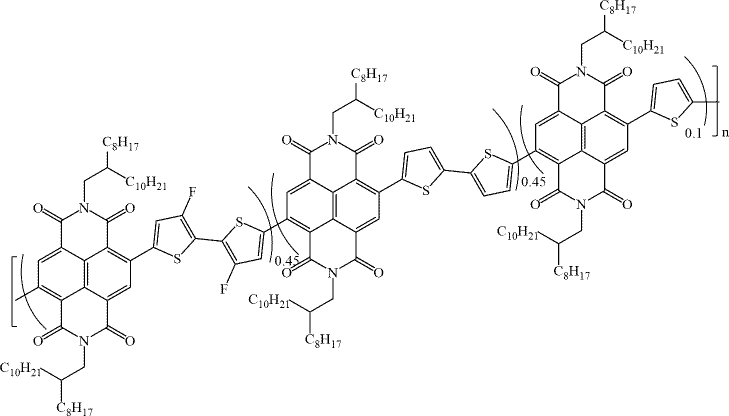

PC₆₁BM: [6,6]-phenyl-C61-methyl butyrate (a fullerene-based organic semiconductor) PC₇₁BM: [6,6]-phenyl-C71-methyl butyrate (a fullerene-based organic semiconductor) PTB7: A compound having the following structure ((poly({4,8-bis[(2-ethylhexyl)oxy]benzo[1,2-b:4,5-b′]dithiophen-2,6-diyl}{3-fluoro-2-[(2-ethylhexyl)carbonyl]thieno[3,4-b]thiophendiyl})), weight-average molecular weight: 80,000 to 200,000)

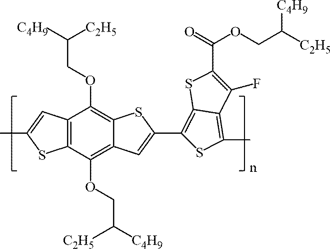

IEICO: A compound having the following structure

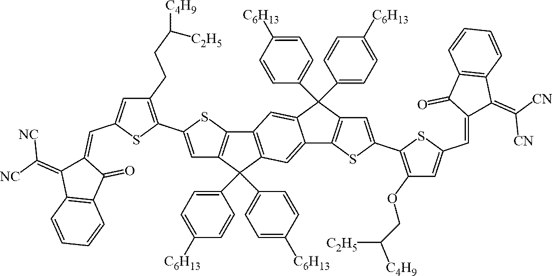

### Evaluation

Dark current and external quantum efficiency (EQE) of the manufactured photodetection elements were evaluated by using a semiconductor parameter analyzer (C4156, manufactured by Agilent Technologies, Inc.).

First, the current-voltage characteristics (I-V characteristics) were measured while sweeping the voltage from 0 V to -2 V in a state of not carrying out irradiation with light, and the dark current was evaluated. Here, the current value at -1 V was defined as a dark current value. Subsequently, the I-V characteristics were measured while sweeping the voltage from 0 V to -2 V in a state of carrying out irradiation with monochrome light of 940 nm. A value obtained by subtracting the dark current value from the current value in a state where -0.5 V was applied was defined as the photocurrent value, and the external quantum efficiency (EQE) was calculated from the photocurrent value.

TABLE 2

| | EQE (%) | Dark current (A/cm²) |
|---|---|---|
| Example 1 | 10.2 | 3.1×10⁻⁶ |
| Example 2 | 10.8 | 2.9×10⁻⁶ |
| Example 3 | 10.5 | 3.4×10⁻⁶ |
| Example 4 | 10.3 | 3.3×10⁻⁶ |
| Example 5 | 9.6 | 4.1×10⁻⁶ |
| Example 6 | 8.9 | 5.5×10⁻⁶ |
| Example 7 | 10.9 | 1.9×10⁻⁶ |
| Example 8 | 11.9 | 1.1×10⁻⁶ |
| Example 9 | 11.3 | 1.5×10⁻⁶ |
| Example 10 | 12.5 | 9.1×10⁻⁷ |
| Example 11 | 11.8 | 9.8×10⁻⁷ |
| Example 12 | 12.8 | 7.6×10⁻⁷ |
| Example 13 | 13.6 | 6.5×10⁻⁷ |
| Example 14 | 11.1 | 1.6×10⁻⁶ |
| Example 15 | 12.5 | 5.2×10⁻⁶ |
| Example 16 | 14.7 | 4.9×10⁻⁶ |
| Comparative Example 1 | 6.0 | 6.8×10⁻⁶ |

As shown in the above table, it has been confirmed that the dark current of the photodetection element of Examples is low, and the external quantum efficiency (EQE) is high.

In a case where an image sensor is produced by a known method by using the photodetection element obtained in Example described and incorporating it into a solid-state imaging element together with an optical filter produced according to the methods disclosed in WO2016/186050A and WO2016/190162A, it is possible to obtain an image sensor having good visible and infrared imaging performance.

### EXPLANATION OF REFERENCES

1: photodetection element
11: first electrode layer
12: second electrode layer
13: photoelectric conversion layer
21: electron transport layer
22: hole transport layer

What is claimed is:

1. A photodetection element comprising:
a first electrode layer;
a second electrode layer;
a photoelectric conversion layer provided between the first electrode layer and the second electrode layer;
an electron transport layer provided between the first electrode layer and the photoelectric conversion layer; and
a hole transport layer provided between the photoelectric conversion layer and the second electrode layer,
wherein the photoelectric conversion layer contains quantum dots of a compound semiconductor containing an Ag element and a Bi element, and
the hole transport layer contains an organic semiconductor A including a structure represented by any one of Formulae 3-1 to 3-5, 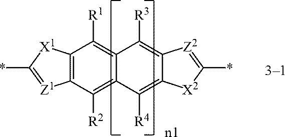 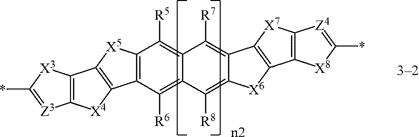 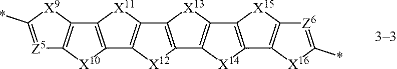 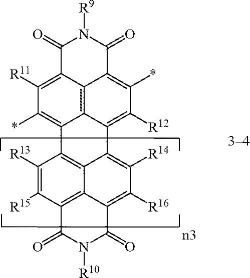 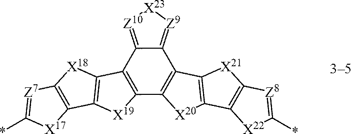
in Formula 3-1, X¹ and X² each independently represent S, O, Se, NR^{X1}, or CR^{X2}R^{X3}, where R^{X1} to R^{X3} each independently represent a hydrogen atom or a substituent,
Z¹ and Z² each independently represent N or CR^{Z1}, where R^{Z1} represents a hydrogen atom or a substituent,
R¹ to R⁴ each independently represent a hydrogen atom or a substituent,
n1 represents an integer of 0 to 2, and
* represents a bonding site,
provided that at least one of R¹ or R² represents a halogen atom, a hydroxy group, a cyano group, an acylamino group, an acyloxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, a group represented by Formula (R-100), or a group including an intramolecular salt structure, 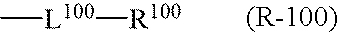
in (R-100), L¹⁰⁰ represents a single bond or a divalent group, and R¹⁰⁰ represents an acid group, a basic group, a group having an anion, or a group having a cation;
in Formula 3-2, X³ to X⁸ each independently represent S, O, Se, NR^{X4}, or CR^{X5}R^{X6}, where R^{X4} to R^{X6} each independently represent a hydrogen atom or a substituent,
Z³ and Z⁴ each independently represent N or CR^{Z2}, where R^{Z2} represents a hydrogen atom or a substituent,
R⁵ to R⁸ each independently represent a hydrogen atom or a substituent,
n2 represents an integer of 0 to 2, and
* represents a bonding site;
in Formula 3-3, X⁹ to X¹⁶ each independently represent S, O, Se, NR^{X7}, or CR^{X8}R^{X9}, where R^{X7} to R^{X9} each independently represent a hydrogen atom or a substituent,
Z⁵ and Z⁶ each independently represent N or CR^{Z3}, where R^{Z3} represents a hydrogen atom or a substituent, and
* represents a bonding site;
in Formula 3-4, R⁹ to R¹⁶ each independently represent a hydrogen atom or a substituent,
n3 represents an integer of 0 to 2, and
* represents a bonding site; and
in Formula 3-5, X¹⁷ to X²³ each independently represent S, O, Se, NR^{X10}, or CR^{X11}R^{X12}, where R^{X10} to R^{X12} each independently represent a hydrogen atom or a substituent,
Z⁷ to Z¹⁰ each independently represent N or CR^{Z4}, where R^{Z4} represents a hydrogen atom or a substituent, and
* represents a bonding site.

2. The photodetection element according to claim 1,
wherein the organic semiconductor A is a compound including a structure represented by Formula 3-1 or a compound including a structure represented by Formula 3-4.

3. The photodetection element according to claim 1, wherein the organic semiconductor A further includes a structure represented by Formula 4, 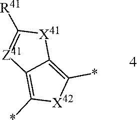
in Formula 4, X⁴¹ and X⁴² each independently represent S, O, Se, NR^{X41}, or CR^{X42}R^{X43}, where R^{X41} to R^{X43} each independently represent a hydrogen atom or a substituent,
Z⁴¹ represents N or CR^{Z41}, where R^{Z41} represents a hydrogen atom or a substituent,
R⁴¹ represents a hydrogen atom or a substituent, and
* represents a bonding site.

4. The photodetection element according to claim 1,
wherein the organic semiconductor A has a group represented by Formula (R-100) or a group including an intramolecular salt structure.

5. The photodetection element according to claim 1,
wherein the organic semiconductor A is a compound including a structure represented by Formula 5, 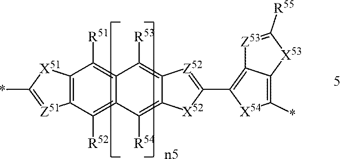
in Formula 5, X⁵¹ to X⁵⁴ each independently represent S, O, Se, NR^{X51}, or CR^{X52}R^{X53}, where R^{X51} to R^{X53} each independently represent a hydrogen atom or a substituent,
Z⁵¹ to Z⁵³ each independently represent N or CR^{Z51}, where R^{Z51} represents a hydrogen atom or a substituent,
R⁵¹ to R⁵⁵ each independently represent a hydrogen atom or a substituent,
n5 represents an integer of 0 to 2, and
* represents a bonding site; and
provided that at least one of R⁵¹ or R⁵² represents a halogen atom, a hydroxy group, a cyano group, an amino group, an acylamino group, an acyloxy group, a carboxy group, an acyl group, an alkoxycarbonyl group, an aryloxycarbonyl group, a silyl group, an alkyl group, an alkenyl group, an alkynyl group, an aryl group, an aryloxy group, an alkylthio group, an arylthio group, a heteroaryl group, the group represented by Formula (R-100), or a group including an intramolecular salt structure.

6. The photodetection element according to claim 1,
wherein the hole transport layer contains two or more kinds of the organic semiconductors A.

7. The photodetection element according to claim 1,
wherein the hole transport layer contains the organic semiconductor A and an organic semiconductor other than the organic semiconductor A.

8. The photodetection element according to claim 7,
wherein the organic semiconductor other than the organic semiconductor A is a fullerene-based organic semiconductor.

9. The photodetection element according to claim 1,
wherein the compound semiconductor of the quantum dots further contains at least one element selected from an element S or an element Te.

10. The photodetection element according to claim 1,
wherein the photoelectric conversion layer contains a ligand that is coordinated to the quantum dots.

11. The photodetection element according to claim 10,
wherein the ligand contains at least one selected from a ligand containing a halogen atom or a polydentate ligand containing two or more coordination moieties.

12. An image sensor comprising:
the photodetection element according to claim 1.
